(19) United States
(12) Patent Application Publication
(10) Pub. No.: US 2017/0093160 A1
(43) Pub. Date: Mar. 30, 2017

(54) SYSTEMS AND METHODS FOR SECONDARY VOLTAGE LOSS ESTIMATOR

(71) Applicant: Utilidata, Inc., Providence, RI (US)

(72) Inventor: David Gordon Bell, Spokane, WA (US)

(21) Appl. No.: 15/274,219

(22) Filed: Sep. 23, 2016

Related U.S. Application Data
(60) Provisional application No. 62/232,105, filed on Sep. 24, 2015.

(51) Int. Cl. H02J 3/18; G05B 15/02; G01R 22/10; H02J 13/00; G01R 31/42; G01R 19/165

(52) U.S. Cl. CPC H02J 3/18; G01R 31/42; G01R 19/16547; G01R 22/10; H02J 13/0006; G05B 15/02

(57) ABSTRACT

The present disclosure is directed to systems and methods of managing power delivery in a utility grid. A controller receives, from one or more metering devices, samples of characteristics of electricity delivered from a power source to one or more consumer sites. The controller generates weights for the samples of characteristics of electricity to compensate for void samples at the controller. The controller determines one or more parameters using the weights applied to the samples of characteristics of electricity. The controller determines a secondary voltage drop based on the one or more parameters. The controller adjusts, based on the determined secondary voltage drop, a primary voltage setpoint used to establish a voltage level provided to the distribution transformer by a regulating transformer located at the primary distribution level.

### CROSS-REFERENCES TO RELATED APPLICATIONS

This application is a continuation of and claims priority to, and the benefit of, U.S. Provisional Patent Application No. 62/232,105, filed Sep. 24, 2015, which is incorporated herein by reference in their entirety.

### FIELD OF THE DISCLOSURE

This disclosure relates generally to systems and methods for estimating the secondary voltage drop for sites equipped with metering devices. By estimating the secondary voltage drop using the techniques disclosed herein, systems and methods of the present disclosure can facilitate voltage regulation.

### BACKGROUND

When supplying a utility such as electrical power to consumers, several needs compete and should be considered in managing electrical power distribution. Factors to be considered can include, e.g., (1) maintaining delivered electrical power voltage levels within predetermined limits; (2) improving overall efficiency of electrical power usage and distribution; and (3) managing these concerns in light of changing electrical loading of the system and variations in the character of the loading so that the voltages do not decrease to such a level that the devices shut down or function improperly.

One way to accommodate changes in electrical loading is to set preset threshold levels at which the voltage level of the distribution system changes. When the system detects a change in the voltage level, a tap change is initiated (on a multiple-tap transformer) resulting in a system voltage change. To detect changes, systems can obtain measurements from metering devices located at various points in a distribution grid. However, due to large amounts of data, imperfect data transmission, or minimal data collection abilities of a metering device, it can be challenging to determine certain characteristics associated with electricity using the measurements from the metering devices.

### BRIEF SUMMARY OF THE DISCLOSURE

Systems and methods of the present disclosure are directed to estimating a characteristic of electricity at a location in a utility grid and applying such estimates to the control of electrical system voltage levels. More specifically, the present solution can include a hybrid estimator that uses primary voltage observations and secondary voltage observations to estimate a secondary voltage drop when there is incomplete observation information. The system can use the estimated or determined secondary voltage drop to adjust a primary voltage lower bound of an elastic decision boundary used to control a voltage level of a primary distribution circuit. Secondary voltage can refer to a customer service voltage, and a secondary voltage drop can refer to the difference between the distribution primary voltage and the service point voltage. The secondary voltage and the secondary voltage can be referenced to the same basis voltage. The present disclosure can facilitate estimating a secondary voltage drop at a customer site using advanced metering infrastructure (“AMI”) of the utility grid. The AMI system provides information about the electricity supplied from a power source to one or more customer sites. Since the amount or type of information provided by AMI systems can vary based on a type of AMI metering device, or configuration or operation of the AMI system, the present disclosure can facilitate estimating the characteristic of electricity using a minimal signal complement obtained via AMI systems. The minimal signal complement can refer to less than complete information provided by an AMI system. For example, the minimal signal complement can refer to physical observations in a given interval that are (a) unsuitable for statistically satisfactory estimates, or (b) incomplete with respect to physical quantities of interest in the characterization of consumer energy demand processes.

In some embodiments, the secondary voltage drop can refer to the sum of voltage drops in the conductors connecting a customer to the secondary of a distribution transformer and the voltage drop in the transformer due to loading, the latter a consequence of the electrical impedance of the transformer. This voltage drop reduces the voltage being supplied at a customer site (or connection point) in an electrical grid infrastructure. The present disclosure can estimate this secondary voltage using historical information about characteristics of electricity supplied from the power source to customer sites.

At least one aspect is directed to a system for determining, identifying, modeling or estimating a secondary voltage drop. The secondary voltage drop can be based on a difference between a primary basis voltage that is correlated with an AMI site and a secondary basis voltage measured and reported by the meter at the AMI site. The system can obtain AMI site observations that are sampled at nominally uniform intervals. However, these AMI sample records can include defects that result in missing or otherwise void observations. The probability of occurrence of the defects or void samples can be unknown.

In some embodiments, the system can determine the secondary voltage drop based on a historical estimate of a secondary impedance, a historical estimate of a real demand ratio, a primary real demand, and a primary basis voltage correlated with an AMI site. For example, determining the secondary voltage drop can include determining a first product of the historical secondary estimated impedance, the historical estimated real demand ratio (e.g., ratio of an AMI site's real power demand to a total primary real power demand), and the present primary real demand. The system can divide the first product by the site correlated primary basis voltage to determine the secondary voltage drop.

In some embodiments, determining the secondary voltage drop includes determining, identifying, modeling or estimating additional values or parameters based on characteristics of electricity. The parameters can include, e.g., a primary real demand, primary basis voltage, estimated secondary impedance, estimated real demand ratio, secondary real demand, secondary basis voltage, secondary voltage drop, historical weights, and a site correlated primary basis voltage. The parameters can be based on samples of characteristics of electricity corresponding to a sampling time interval such as 15 minutes or 60 minutes, including samples observed over a time interval such as 12 hours, 24 hours, a week, 30 days, 90 days, a season, or all available samples.

In some embodiments, the system can apply a weighting technique or weight the historical observations. The weighting technique can account for void or defective observations. For example, the system can determine initial weights, weights for valid observations, and a weight for void observations to generate void-compensated historical weights. The system can be configured to generate a secondary impedance (or also referred to as secondary pseudo-impedance) value using the void-compensated historical weights. The system can be further configured to generate a real demand ratio and a site correlated primary basis voltage using the void-compensated historical weights. With the generated void-compensated secondary impedance, real demand ratio and site correlated primary basis voltage, the system can be further configured to determine the secondary voltage drop. For example, the system can determine a product of the void-compensated historically weighted secondary pseudo impedance, real demand ratio, and primary real demand. The system can further divide the product by the void-compensated historically weighted primary basis voltage to determine the void compensated secondary voltage drop.

The system can use the estimated or determined secondary voltage drop to adjust a primary voltage lower bound of an elastic decision boundary used to control a voltage level of a primary distribution circuit. For example, the system can determine an amount by which to adjust or reduce a primary voltage lower bound value based on a difference between a site correlated primary basis voltage, a minimum allowable delivery site voltage, and an aggregated secondary voltage drop (e.g., mean secondary voltage drop of a subset of determined secondary voltage drops).

The system can then adjust the primary voltage lower bound based on the determined secondary voltage drop information, and use the adjusted primary voltage lower bound to adjust a characteristic of energy supplied via the electrical grid to a consumer. For example, the system can generate a control signal to adjust a parameter of a Voltage/Volt-Ampere Reactive control or optimization system (“VVC” or “VVO”). The parameter can include, e.g., a voltage setpoint that can be used as part of a control decision procedure to adjust a voltage tap setting.

At least one aspect is directed to a method of managing power delivery in a utility grid. The method can include a controller receiving, from one or more metering devices, samples of characteristics of electricity delivered from a power source to one or more consumer sites. The method can include the controller generating weights for the samples of the characteristics of electricity to compensate for void samples. The weights can be generated based on a validity of the samples of the characteristics of electricity to compensate for void samples at the controller. The method can include the controller determining one or more parameters indicative of power demand of the utility grid using the weights applied to the samples of characteristics of electricity. The one or more parameters can include, for example, a real demand ratio, a primary basis voltage, and an impedance based on the characteristics of electricity. The method can include the controller determining a secondary voltage drop based on the one or more parameters determined using the weights applied to the samples of the characteristics of electricity. The secondary voltage drop can correspond to a distribution transformer located between a primary distribution level of the utility grid and a secondary distribution level of the utility grid corresponding to the one or more sites. The method can include the controller adjusting, based on the determined secondary voltage drop a primary voltage setpoint used to establish a voltage level provided to the distribution transformer by a regulating transformer located at the primary distribution level.

In some embodiments, the controller can receive, during a first time interval, a first plurality of samples of the characteristics of electricity from the one or more metering devices corresponding to the one or more consumer sites. The first plurality of samples can be correlated with the one or more metering devices. The controller can receive, during a second time interval, a second plurality of samples of the characteristics of electricity from the one or more metering devices corresponding to the one or more consumer sites. The second plurality of samples can be correlated with the one or more metering devices. The characteristics of electricity indicate at least one of voltage information, primary voltage information, secondary voltage information, primary real demand, or secondary real demand. In some cases, the controller can determine the secondary voltage drop based on the characteristics of electricity delivered during the first time interval and the characteristics of electricity delivered during the second time interval.

The controller can generate, for each valid sample of the samples of the characteristics of electricity, a weight using a first weighting function. The controller can generate, for each invalid sample of the samples of the characteristics of electricity, a weight using a second weighting function. The controller can combine the weight generated using the first weighting function and the weight generated using the second weighting function to generate the weights for the characteristics of electricity. In some embodiments, the controller can determine, for each valid sample of the samples of the characteristics of electricity, a weight using a sigmoid inflection slope for a predetermined time interval to generate the weights for the characteristics of electricity.

The controller can determine the real demand ratio for each of the one or more sites based on a ratio of a secondary real demand to a primary real demand for each of the one or more sites.

In some embodiments, the controller can determine a real demand for at least one metering site of the one or more metering sites. The controller can exclude, responsive to a comparison of the real demand for the at least one metering site with a threshold, the at least one metering site from the determination of the secondary voltage drop. In some embodiments, the controller can determine a threshold based on a mean demand for the one or more metering sites. The controller can determine that a real demand for at least one metering site of the one or more metering sites is less than or equal to the threshold. The controller can exclude, responsive to the real demand for the at least one metering site less than or equal to the threshold the at least one metering site from the determination of the secondary voltage drop.

The secondary voltage drop can include a sum of voltage drops in conductors connecting the one or more consumer sites to a secondary terminal of the distribution transformer and a voltage drop in the distribution transformer due to loading.

In some embodiments, the controller can adjust the decision boundary which includes a primary lower bound based on the secondary voltage drop. The controller can determine the primary voltage setpoint using the adjusted primary lower bound. The controller can provide a signal to adjust a tap setting of the regulating transformer responsive to implementation of the control processes using the determined voltage setpoint.

At least one aspect is directed to a system to manage power delivery in a utility grid. The system can include a controller comprising one or more processors. The controller can receive, from one or more metering devices, samples of characteristics of electricity delivered from a power source to one or more consumer sites. The controller generate weights for the characteristics of electricity to compensate for void samples. For example, weights can be generated based on a validity of samples of the characteristics of electricity. The controller can determine one or more parameters using the weights applied to the samples. The one or more parameters can include, for example, a real demand ratio, a primary basis voltage, and an impedance based on the characteristics of electricity. The controller can determine a secondary voltage drop based on the determined one or more parameters, such as the real demand ratio, the primary basis voltage, and the impedance. The secondary voltage drop can correspond to a distribution transformer located between a primary distribution level of the utility grid and a secondary distribution level of the utility grid corresponding to the one or more sites. The controller can adjust, based on the determined secondary voltage drop, a decision boundary for a primary voltage setpoint used to establish a voltage level provided to the distribution transformer by a regulating transformer located at the primary distribution level.

In some embodiments, the controller can receive, during a first time interval, a first plurality of samples of the characteristics of electricity from the one or more metering devices corresponding to the one or more consumer sites. The first plurality of samples can be correlated with the one or more metering devices. The controller can receive, during a second time interval, a second plurality of samples of the characteristics of electricity from the one or more metering devices corresponding to the one or more consumer sites. The second plurality of samples can be correlated with the one or more metering devices. The characteristics of electricity indicate at least one of voltage information, primary voltage information, secondary voltage information, primary real demand, or secondary real demand. In some cases, the controller can determine the secondary voltage drop based on the characteristics of electricity delivered during the first time interval and the characteristics of electricity delivered during the second time interval.

The controller can generate, for each valid sample of the samples of the characteristics of electricity, a weight using a first weighting function. The controller can generate, for each invalid sample of the samples of the characteristics of electricity, a weight using a second weighting function. The controller can combine the weight generated using the first weighting function and the weight generated using the second weighting function to generate the weights for the characteristics of electricity. In some embodiments, the controller can determine, for each valid sample of the samples of the characteristics of electricity, a weight using a sigmoid inflection slope for a predetermined time interval to generate the weights for the characteristics of electricity.

The controller can determine the real demand ratio for each of the one or more sites based on a ratio of a secondary real demand to a primary real demand for each of the one or more sites.

In some embodiments, the controller can determine a real demand for at least one metering site of the one or more metering sites. The controller can exclude, responsive to a comparison of the real demand for the at least one metering site with a threshold, the at least one metering site from the determination of the secondary voltage drop. In some embodiments, the controller can determine a threshold based on a mean demand for the one or more metering sites. The controller can determine that a real demand for at least one metering site of the one or more metering sites is less than or equal to the threshold. The controller can exclude, responsive to the real demand for the at least one metering site less than or equal to the threshold the at least one metering site from the determination of the secondary voltage drop.

The secondary voltage drop can include a sum of voltage drops in conductors connecting the one or more consumer sites to a secondary terminal of the distribution transformer and a voltage drop in the distribution transformer due to loading.

In some embodiments, the controller can adjust the decision boundary which includes a primary lower bound based on the secondary voltage drop. The controller can determine the primary voltage setpoint using the adjusted primary lower bound. The controller can provide a signal to adjust a tap setting of the regulating transformer responsive to implementation of the control processes using the determined voltage setpoint.

### BRIEF DESCRIPTION OF THE FIGURES

The details of one or more embodiments of the subject matter described in this specification are set forth in the accompanying drawings and the description below. Other features, aspects, and advantages of the subject matter will become apparent from the description, the drawings, and the claims.

FIG. 1 is a block diagram depicting an illustrative utility grid in accordance with an embodiment.

FIGS. 2A and 2B are block diagrams depicting embodiments of computing devices useful in connection with the systems and methods described herein.

FIG. 3 is a schematic diagram of a voltage signal processing element shown in FIG. 1 that processes measured voltage signals to provide a selected voltage signal for tap regulation, in accordance with an embodiment;

FIG. 4 is a flow chart of an embodiment of a process for determining a voltage adjustment decision by the voltage controller shown in FIG. 3;

FIG. 5 is a diagram illustrating elastic decision boundaries used by the voltage control system in accordance with an embodiment.

FIG. 6 is a bock diagram depicting a system for estimating a secondary voltage drop in a utility grid in accordance with an embodiment.

FIG. 7 is a flow diagram of an embodiment of a method of estimating a secondary voltage drop in a utility grid.

The features and advantages of the present solution will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

For purposes of reading the description of the various embodiments below, the following descriptions of the sections of the specification and their respective contents may be helpful:

Section A describes a utility distribution environment which can be useful for practicing embodiments described herein;

Section B describes a networking and computing environment which can be useful for practicing embodiments described herein;

Section C describes measuring and processing voltage signals to regulate a voltage tap setting which can be useful for practicing embodiments described herein; and

Section D describes embodiments of systems and methods of estimating secondary voltage loss.

A. Utility Distribution Environment

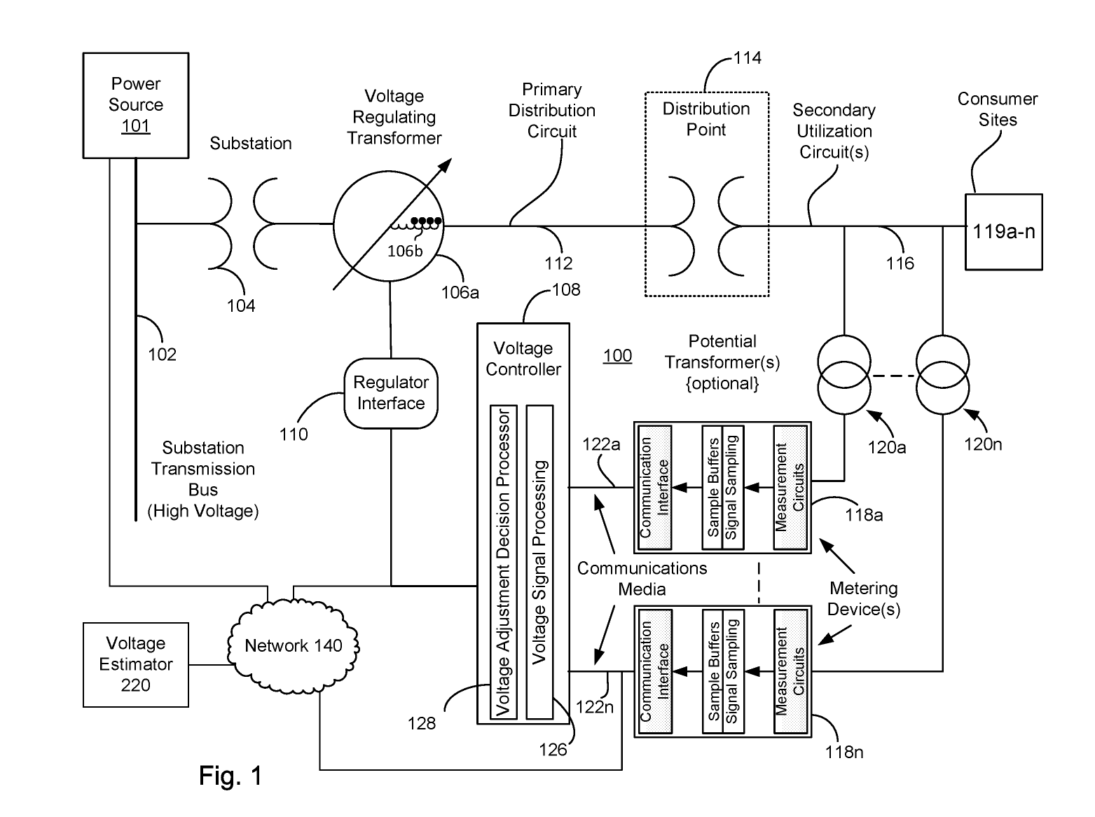

Prior to discussing the specifics of embodiments of the systems and methods of estimating a secondary voltage drop in a utility distribution grid, it may be helpful to discuss the utility distribution environment. Referring now to FIG. 1, an embodiment of a utility distribution environment is shown. The utility distribution environment can include a utility grid 100. The utility grid 100 can include an electricity distribution grid with one or more devices, assets, or digital computational devices and systems, such as computing device 200. In brief overview, the utility grid 100 includes a power source 101 that can be connected via a subsystem transmission bus 102 and/or via substation transformer 104 to a voltage regulating transformer 106a. The voltage regulating transformer 106a can be controlled by voltage controller 108 with regulator interface 110. Voltage regulating transformer 106a can be optionally coupled on primary distribution circuit 112 via optional distribution transformer 114 to secondary utilization circuits 116 and to one or more electrical or electronic devices 119. Voltage regulating transformer 106a can include multiple tap outputs 106b with each tap output 106b supplying electricity with a different voltage level. The utility grid 100 can include monitoring devices 118a-118n that can be coupled through optional potential transformers 120a-120n to secondary utilization circuits 116. The monitoring or metering devices 118a-118n can detect (e.g., continuously, periodically, based on a time interval, responsive to an event or trigger) measurements and continuous voltage signals of electricity supplied to one or more electrical devices 119 connected to circuit 112 or 116 from a power source 101 coupled to bus 102. A voltage controller 108 can receive, via a communication media 122, measurements obtained by the metering devices 118a-118n, and use the measurements to make a determination regarding a voltage tap settings, and provide an indication to regulator interface 110. The regulator interface can communicate with voltage regulating transformer 106a to adjust an output tap level 106b.

Still referring to FIG. 1, and in further detail, the utility grid 100 includes a power source 101. The power source 101 can include a power plant such as an installation configured to generate electrical power for distribution. The power source 101 can include an engine or other apparatus that generates electrical power. The power source 101 can create electrical power by converting power or energy from one state to another state. In some embodiments, the power source 101 can be referred to or include a power plant, power station, generating station, powerhouse or generating plant. In some embodiments, the power source 101 can include a generator, such as a rotating machine that converts mechanical power into electrical power by creating relative motion between a magnetic field and a conductor. The power source 101 can use one or more energy source to turn the generator including, e.g., fossil fuels such as coal, oil, and natural gas, nuclear power, or cleaner renewable sources such as solar, wind, wave and hydroelectric.

In some embodiments, the utility grid 100 includes one or more substation transmission bus 102. The substation transmission bus 102 can include or refer to transmission tower, such as a structure (e.g., a steel lattice tower, concrete, wood, etc.), that supports an overhead power line used to distribute electricity from a power source 101 to a substation 104 or distribution point 114. Transmission towers 102 can be used in high-voltage AC and DC systems, and come in a wide variety of shapes and sizes. In an illustrative example, a transmission tower can range in height from 15 to 55 meters or more. Transmission towers 102 can be of various types including, e.g., suspension, terminal, tension, and transposition. In some embodiments, the utility grid 100 can include underground power lines in addition to or instead of transmission towers 102.

In some embodiments, the utility gird 100 includes a substation 104 or electrical substation 104 or substation transformer 104. A substation can be part of an electrical generation, transmission, and distribution system. In some embodiments, the substation 104 transform voltage from high to low, or the reverse, or performs any of several other functions to facilitate the distribution of electricity. In some embodiments, the utility grid 100 can include several substations 104 between the power plant 101 and the consumer electoral devices 119 with electric power flowing through them at different voltage levels.

In some embodiments, the substations 104 can be remotely operated, supervised and controlled (e.g., via a supervisory control and data acquisition system). A substation can include one or more transformers to change voltage levels between high transmission voltages and lower distribution voltages, or at the interconnection of two different transmission voltages.

In some embodiments, the regulating transformer 106 is can include: (1) a multi-tap autotransformer (single or three phase), which are used for distribution; or (2) on-load tap changer (three phase transformer), which can be integrated into a substation transformer 104 and used for both transmission and distribution. The illustrated system described herein can be implemented as either a single-phase or three-phase distribution system. The utility grid 100 can include an alternating current (AC) power distribution system and the term voltage can refer to an “RMS Voltage”, in some embodiments.

In some embodiments, the utility grid 100 includes a distribution point 114 or distribution transformer 114, which can refer to an electric power distribution system. In some embodiments, the distribution point 114 can be a final or near final stage in the delivery of electric power. For example, the distribution point 114 can carry electricity from the transmission system (which can include one or more transmission towers 102) to individual consumers 119. In some embodiments, the distribution system can include the substations 104 and connect to the transmission system to lower the transmission voltage to medium voltage ranging between 2 kV and 35 kV with the use of transformers, for example. Primary distribution lines or circuit 112 carry this medium voltage power to distribution transformers located near the customer's premises 119. Distribution transformers can further lower the voltage to the utilization voltage of appliances and can feed several customers 119 through secondary distribution lines or circuits 116 at this voltage. Commercial and residential customers 119 can be connected to the secondary distribution lines through service drops. In some embodiments, customers demanding high load can be connected directly at the primary distribution level or the sub-transmission level.

In some embodiments, the utility grid 100 includes or couples to one or more consumer sites 119. Consumer sites 119 can include, for example, a building, house, shopping mall, factory, office building, residential building, commercial building, stadium, movie theater, etc. The consumer sites 119 can be configured to receive electricity from the distribution point 114 via a power line (above ground or underground). In some embodiments, a consumer site 119 can be coupled to the distribution point 114 via a power line. In some embodiments, the consumer site 119 can be further coupled to a site meter 118a-n or advanced metering infrastructure (“AMI”). The site meter 118a-n can be associated with a controllable primary circuit segment 112. The association can be stored as a pointer, link, field, data record, or other indicator in a data file in a database.

In some embodiments, the utility grid 100 includes site meters 118a-n or AMI. Site meters 118a-n can measure, collect, and analyze energy usage, and communicate with metering devices such as electricity meters, gas meters, heat meters, and water meters, either on request or on a schedule. Site meters 118a-n can include hardware, software, communications, consumer energy displays and controllers, customer associated systems, Meter Data Management (MDM) software, or supplier business systems. In some embodiments, the site meters 118a-n can obtain samples of electricity usage in real time or based on a time interval, and convey, transmit or otherwise provide the information. In some embodiments, the information collected by the site meter can be referred to as meter observations or metering observations and can include the samples of electricity usage. In some embodiments, the site meter 118a-n can convey the metering observations along with additional information such as a unique identifier of the site meter 118a-n, unique identifier of the consumer, a time stamp, date stamp, temperature reading, humidity reading, ambient temperature reading, etc. In some embodiments, each consumer site 119 (or electronic device) can include or be coupled to a corresponding site meter or monitoring device 118a-118n.

Monitoring devices 118a-118n can be coupled through communications media 122a-122n to voltage controller 108. Voltage controller 108 can compute (e.g., discrete-time, continuously or based on a time interval or responsive to a condition/event) values for electricity that facilitates regulating or controlling electricity supplied or provided via the utility grid. For example, the voltage controller 108 can compute estimated deviant voltage levels that the supplied electricity (e.g., supplied from power source 101) will not drop below or exceed as a result of varying electrical consumption by the one or more electrical devices 119. The deviant voltage levels can be computed based on a predetermined confidence level and the detected measurements. Voltage controller 108 can include a voltage signal processing circuit 126 that receives sampled signals from metering devices 118a-118n. Metering devices 118a-118n can process and sample the voltage signals such that the sampled voltage signals are sampled as a time series (e.g., uniform time series free of spectral aliases or non-uniform time series).

Voltage signal processing circuit 126 can receive signals via communications media 122a-n from metering devices 118a-n, process the signals, and feed them to voltage adjustment decision processor circuit 128. Although the term “circuit” is used in this description, the term is not meant to limit this disclosure to a particular type of hardware or design, and other terms known generally known such as the term “element”, “hardware”, “device” or “apparatus” could be used synonymously with or in place of term “circuit” and can perform the same function. For example, in some embodiments the functionality can be carried out using one or more digital processors, e.g., implementing one or more digital signal processing algorithms. Adjustment decision processor circuit 128 can determine a voltage location with respect to a defined decision boundary and set the tap position and settings in response to the determined location. For example, the adjustment decision processing circuit 128 in voltage controller 108 can compute a deviant voltage level that is used to adjust the voltage level output of electricity supplied to the electrical device. Thus, one of the multiple tap settings of regulating transformer 106 can be continuously selected by voltage controller 108 via regulator interface 110 to supply electricity to the one or more electrical devices based on the computed deviant voltage level. The voltage controller 108 can also receive information about voltage regulator transformer 106a or output tap settings 106b via the regulator interface 110. Regulator interface 110 can include a processor controlled circuit for selecting one of the multiple tap settings in voltage regulating transformer 106 in response to an indication signal from voltage controller 108. As the computed deviant voltage level changes, other tap settings 106b (or settings) of regulating transformer 106a are selected by voltage controller 108 to change the voltage level of the electricity supplied to the one or more electrical devices 119.

The network 140 can be connected via wired or wireless links. Wired links can include Digital Subscriber Line (DSL), coaxial cable lines, or optical fiber lines. The wireless links can include BLUETOOTH, Wi-Fi, Worldwide Interoperability for Microwave Access (WiMAX), an infrared channel or satellite band. The wireless links can also include any cellular network standards used to communicate among mobile devices, including standards that qualify as 1G, 2G, 3G, or 4G. The network standards can qualify as one or more generation of mobile telecommunication standards by fulfilling a specification or standards such as the specifications maintained by International Telecommunication Union. The 3G standards, for example, can correspond to the International Mobile Telecommunications-2000 (IMT-2000) specification, and the 4G standards can correspond to the International Mobile Telecommunications Advanced (IMT-Advanced) specification. Examples of cellular network standards include AMPS, GSM, GPRS, UMTS, LTE, LTE Advanced, Mobile WiMAX, and WiMAX-Advanced. Cellular network standards can use various channel access methods e.g. FDMA, TDMA, CDMA, or SDMA. In some embodiments, different types of data can be transmitted via different links and standards. In other embodiments, the same types of data can be transmitted via different links and standards.

The network 140 can be any type and/or form of network. The geographical scope of the network 140 can vary widely and the network 140 can be a body area network (BAN), a personal area network (PAN), a local-area network (LAN), e.g. Intranet, a metropolitan area network (MAN), a wide area network (WAN), or the Internet. The topology of the network 140 can be of any form and can include, e.g., any of the following: point-to-point, bus, star, ring, mesh, or tree. The network 140 can be an overlay network which is virtual and sits on top of one or more layers of other networks 104′. The network 140 can be of any such network topology as known to those ordinarily skilled in the art capable of supporting the operations described herein. The network 140 can utilize different techniques and layers or stacks of protocols, including, e.g., the Ethernet protocol, the internet protocol suite (TCP/IP), the ATM (Asynchronous Transfer Mode) technique, the SONET (Synchronous Optical Networking) protocol, or the SDH (Synchronous Digital Hierarchy) protocol. The TCP/IP internet protocol suite can include application layer, transport layer, internet layer (including, e.g., IPv6), or the link layer. The network 140 can be a type of a broadcast network, a telecommunications network, a data communication network, or a computer network.

One or more components, assets, or devices of utility grid 100 can communicate via network 140. The utility grid 100 can one or more networks, such as public or private networks. The utility grid 100 can include an anomaly detector 200 designed and constructed to communicate or interface with utility grid 100 via network 140. Each asset, device, or component of utility grid 100 can include one or more computing devices 200 or a portion of computing 200 or a some or all functionality of computing device 200.

B. Networking and Computing Environment

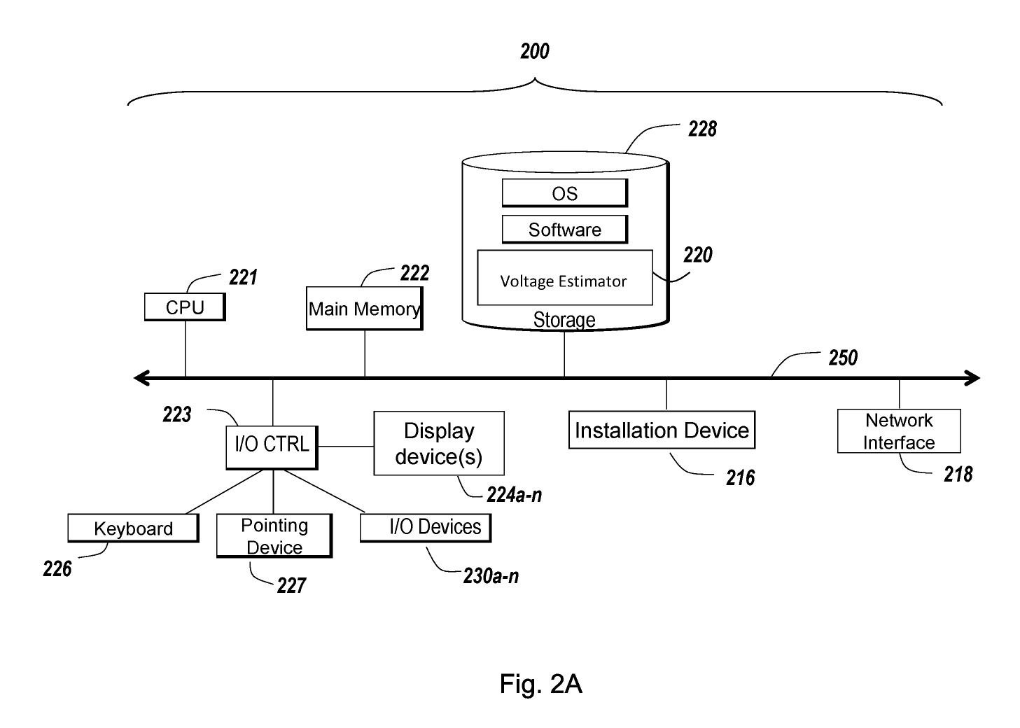

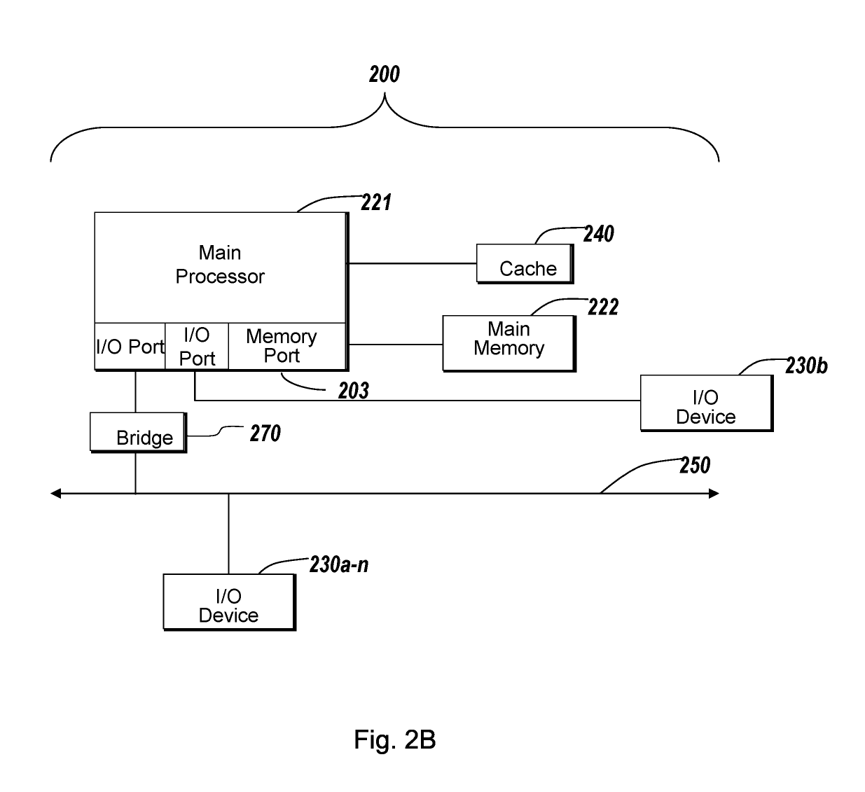

FIGS. 2A and 2B depict block diagrams of a computing device 200. As shown in FIGS. 2A and 2B, each computing device 200 includes a central processing unit 221, and a main memory unit 222. As shown in FIG. 2A, a computing device 200 can include a storage device 228, an installation device 216, a network interface 218, an I/O controller 221, display devices 224a-224n, a keyboard 226 and a pointing device 227, e.g. a mouse. The storage device 228 can include, without limitation, an operating system, software, and a software of a voltage estimator 220. As shown in FIG. 2B, each computing device 200 can also include additional optional elements, e.g. a memory port 203, a bridge 270, one or more input/output devices 230a-230n (generally referred to using reference numeral 230), and a cache memory 240 in communication with the central processing unit 221.

The central processing unit 221 is any logic circuitry that responds to and processes instructions fetched from the main memory unit 222. In many embodiments, the central processing unit 221 is provided by a microprocessor unit, e.g.: those manufactured by Intel Corporation of Mountain View, Calif.; those manufactured by Motorola Corporation of Schaumburg, Ill.; the ARM processor and TEGRA system on a chip (SoC) manufactured by Nvidia of Santa Clara, Calif.; the POWER7 processor, those manufactured by International Business Machines of White Plains, N.Y.; or those manufactured by Advanced Micro Devices of Sunnyvale, Calif. The computing device 200 can be based on any of these processors, or any other processor capable of operating as described herein. The central processing unit 221 can utilize instruction level parallelism, thread level parallelism, different levels of cache, and multi-core processors. A multi-core processor can include two or more processing units on a single computing component. Examples of multi-core processors include the AMD PHENOM IIX2, INTEL CORE i5 and INTEL CORE i7.

Main memory unit 222 can include one or more memory chips capable of storing data and allowing any storage location to be directly accessed by the microprocessor 221. Main memory unit 222 can be volatile and faster than storage 228 memory. Main memory units 222 can be Dynamic random access memory (DRAM) or any variants, including static random access memory (SRAM), Burst SRAM or SynchBurst SRAM (BSRAM), Fast Page Mode DRAM (FPM DRAM), Enhanced DRAM (EDRAIVI), Extended Data Output RAM (EDO RAM), Extended Data Output DRAM (EDO DRAM), Burst Extended Data Output DRAM (BEDO DRAM), Single Data Rate Synchronous DRAM (SDR SDRAM), Double Data Rate SDRAM (DDR SDRAM), Direct Rambus DRAM (DRDRAM), or Extreme Data Rate DRAM (XDR DRAM). In some embodiments, the main memory 222 or the storage 228 can be non-volatile; e.g., non-volatile read access memory (NVRAM), flash memory non-volatile static RAM (nvSRAM), Ferroelectric RAM (FeRAM), Magnetoresistive RAM (MRAM), Phase-change memory (PRAM), conductive-bridging RAM (CBRAM), Silicon-Oxide-Nitride-Oxide-Silicon (SONOS), Resistive RAM (RRAM), Racetrack, Nano-RAM (NRAM), or Millipede memory. The main memory 222 can be based on any of the above described memory chips, or any other available memory chips capable of operating as described herein. In the embodiment shown in FIG. 2A, the processor 221 communicates with main memory 222 via a system bus 250 (described in more detail below). FIG. 2B depicts an embodiment of a computing device 200 in which the processor communicates directly with main memory 222 via a memory port 203. For example, in FIG. 2B the main memory 222 can be DRDRAM.

FIG. 2B depicts an embodiment in which the main processor 221 communicates directly with cache memory 240 via a secondary bus, sometimes referred to as a backside bus. In other embodiments, the main processor 221 communicates with cache memory 240 using the system bus 250. Cache memory 240 typically has a faster response time than main memory 222 and is typically provided by SRAM, BSRAM, or EDRAM. In the embodiment shown in FIG. 2B, the processor 221 communicates with various I/O devices 230 via a local system bus 250. Various buses can be used to connect the central processing unit 221 to any of the I/O devices 230, including a PCI bus, a PCI-X bus, or a PCI-Express bus, or a NuBus. For embodiments in which the I/O device is a video display 224, the processor 221 can use an Advanced Graphics Port (AGP) to communicate with the display 224 or the I/O controller 221 for the display 224. FIG. 2B depicts an embodiment of a computer 200 in which the main processor 221 communicates directly with I/O device 230b or other processors 221′ via HYPERTRANSPORT, RAPIDIO, or INFINIBAND communications technology. FIG. 2B also depicts an embodiment in which local busses and direct communication are mixed: the processor 221 communicates with I/O device 230a using a local interconnect bus while communicating with I/O device 230b directly.

A wide variety of I/O devices 230a-230n can be present in the computing device 200. Input devices can include keyboards, mice, trackpads, trackballs, touchpads, touch mice, multi-touch touchpads and touch mice, microphones, multi-array microphones, drawing tablets, cameras, single-lens reflex camera (SLR), digital SLR (DSLR), CMOS sensors, accelerometers, infrared optical sensors, pressure sensors, magnetometer sensors, angular rate sensors, depth sensors, proximity sensors, ambient light sensors, gyroscopic sensors, or other sensors. Output devices can include video displays, graphical displays, speakers, headphones, inkjet printers, laser printers, and 3D printers.

Devices 230a-230n can include a combination of multiple input or output devices, including, e.g., Microsoft KINECT, Nintendo Wiimote for the WII, Nintendo WII U GAMEPAD, or Apple IPHONE. Some devices 230a-230n allow gesture recognition inputs through combining some of the inputs and outputs. Some devices 230a-230n provides for facial recognition which can be utilized as an input for different purposes including authentication and other commands. Some devices 230a-230n provides for voice recognition and inputs, including, e.g., Microsoft KINECT, SIRI for IPHONE by Apple, Google Now or Google Voice Search.

Additional devices 230a-230n have both input and output capabilities, including, e.g., haptic feedback devices, touchscreen displays, or multi-touch displays. Touchscreen, multi-touch displays, touchpads, touch mice, or other touch sensing devices can use different technologies to sense touch, including, e.g., capacitive, surface capacitive, projected capacitive touch (PCT), in-cell capacitive, resistive, infrared, waveguide, dispersive signal touch (DST), in-cell optical, surface acoustic wave (SAW), bending wave touch (BWT), or force-based sensing technologies. Some multi-touch devices can allow two or more contact points with the surface, allowing advanced functionality including, e.g., pinch, spread, rotate, scroll, or other gestures. Some touchscreen devices, including, e.g., Microsoft PIXELSENSE or Multi-Touch Collaboration Wall, can have larger surfaces, such as on a table-top or on a wall, and can also interact with other electronic devices. Some I/O devices 230a-230n, display devices 224a-224n or group of devices can be augment reality devices. The I/O devices can be controlled by an I/O controller 221 as shown in FIG. 2A. The I/O controller can control one or more I/O devices, such as, e.g., a keyboard 126 and a pointing device 227, e.g., a mouse or optical pen. Furthermore, an I/O device can also provide storage and/or an installation medium 116 for the computing device 200. In still other embodiments, the computing device 200 can provide USB connections (not shown) to receive handheld USB storage devices. In further embodiments, an I/O device 230 can be a bridge between the system bus 250 and an external communication bus, e.g. a USB bus, a SCSI bus, a FireWire bus, an Ethernet bus, a Gigabit Ethernet bus, a Fibre Channel bus, or a Thunderbolt bus.

In some embodiments, display devices 224a-224n can be connected to I/O controller 221. Display devices can include, e.g., liquid crystal displays (LCD), thin film transistor LCD (TFT-LCD), blue phase LCD, electronic papers (e-ink) displays, flexile displays, light emitting diode displays (LED), digital light processing (DLP) displays, liquid crystal on silicon (LCOS) displays, organic light-emitting diode (OLED) displays, active-matrix organic light-emitting diode (AMOLED) displays, liquid crystal laser displays, time-multiplexed optical shutter (TMOS) displays, or 3D displays. Examples of 3D displays can use, e.g. stereoscopy, polarization filters, active shutters, or autostereoscopy. Display devices 224a-224n can also be a head-mounted display (HMD). In some embodiments, display devices 224a-224n or the corresponding I/O controllers 221 can be controlled through or have hardware support for OPENGL or DIRECTX API or other graphics libraries.

In some embodiments, the computing device 200 can include or connect to multiple display devices 224a-224n, which each can be of the same or different type and/or form. As such, any of the I/O devices 230a-230n and/or the I/O controller 221 can include any type and/or form of suitable hardware, software, or combination of hardware and software to support, enable or provide for the connection and use of multiple display devices 224a-224n by the computing device 200. For example, the computing device 200 can include any type and/or form of video adapter, video card, driver, and/or library to interface, communicate, connect or otherwise use the display devices 224a-224n. In one embodiment, a video adapter can include multiple connectors to interface to multiple display devices 224a-224n. In other embodiments, the computing device 200 can include multiple video adapters, with each video adapter connected to one or more of the display devices 224a-224n. In some embodiments, any portion of the operating system of the computing device 200 can be configured for using multiple displays 224a-224n. In other embodiments, one or more of the display devices 224a-224n can be provided by one or more other computing devices 200a or 200b connected to the computing device 200, via the network 140. In some embodiments software can be designed and constructed to use another computer's display device as a second display device 224a for the computing device 200. For example, in one embodiment, an Apple iPad can connect to a computing device 200 and use the display of the device 200 as an additional display screen that can be used as an extended desktop. One ordinarily skilled in the art will recognize and appreciate the various ways and embodiments that a computing device 200 can be configured to have multiple display devices 224a-224n.

Referring again to FIG. 2A, the computing device 200 can comprise a storage device 228 (e.g. one or more hard disk drives or redundant arrays of independent disks) for storing an operating system or other related software, and for storing application software programs such as any program related to the software 220 for the voltage estimator. Examples of storage device 228 include, e.g., hard disk drive (HDD); optical drive including CD drive, DVD drive, or BLU-RAY drive; solid-state drive (SSD); USB flash drive; or any other device suitable for storing data. Some storage devices can include multiple volatile and non-volatile memories, including, e.g., solid state hybrid drives that combine hard disks with solid state cache. Some storage device 228 can be non-volatile, mutable, or read-only. Some storage device 228 can be internal and connect to the computing device 200 via a bus 250. Some storage device 228 can be external and connect to the computing device 200 via a I/O device 230 that provides an external bus. Some storage device 228 can connect to the computing device 200 via the network interface 218 over a network 140, including, e.g., the Remote Disk for MACBOOK AIR by Apple. Some client devices 200 can not require a non-volatile storage device 228 and can be thin clients or zero clients 202. Some storage device 228 can also be used as an installation device 216, and can be suitable for installing software and programs. Additionally, the operating system and the software can be run from a bootable medium, for example, a bootable CD, e.g. KNOPPIX, a bootable CD for GNU/Linux that is available as a GNU/Linux distribution from knoppix.net.

Computing device 200 can also install software or application from an application distribution platform. Examples of application distribution platforms include the App Store for iOS provided by Apple, Inc., the Mac App Store provided by Apple, Inc., GOOGLE PLAY for Android OS provided by Google Inc., Chrome Web store for CHROME OS provided by Google Inc., and Amazon Appstore for Android OS and KINDLE FIRE provided by Amazon.com, Inc.

Furthermore, the computing device 200 can include a network interface 218 to interface to the network 140 through a variety of connections including, but not limited to, standard telephone lines LAN or WAN links (e.g., 802.11, T1, T3, Gigabit Ethernet, Infiniband), broadband connections (e.g., ISDN, Frame Relay, ATM, Gigabit Ethernet, Ethernet-over-SONET, ADSL, VDSL, BPON, GPON, fiber optical including FiOS), wireless connections, or some combination of any or all of the above. Connections can be established using a variety of communication protocols (e.g., TCP/IP, Ethernet, ARCNET, SONET, SDH, Fiber Distributed Data Interface (FDDI), IEEE 802.11a/b/g/n/ac CDMA, GSM, WiMax and direct asynchronous connections). In one embodiment, the computing device 200 communicates with other computing devices 200′ via any type and/or form of gateway or tunneling protocol e.g. Secure Socket Layer (SSL) or Transport Layer Security (TLS), or the Citrix Gateway Protocol manufactured by Citrix Systems, Inc. of Ft. Lauderdale, Fla. The network interface 118 can comprise a built-in network adapter, network interface card, PCMCIA network card, EXPRESSCARD network card, card bus network adapter, wireless network adapter, USB network adapter, modem or any other device suitable for interfacing the computing device 200 to any type of network capable of communication and performing the operations described herein.

A computing device 200 of the sort depicted in FIG. 2A can operate under the control of an operating system, which controls scheduling of tasks and access to system resources. The computing device 200 can be running any operating system such as any of the versions of the MICROSOFT WINDOWS operating systems, the different releases of the Unix and Linux operating systems, any version of the MAC OS for Macintosh computers, any embedded operating system, any real-time operating system, any open source operating system, any proprietary operating system, any operating systems for mobile computing devices, or any other operating system capable of running on the computing device and performing the operations described herein. Typical operating systems include, but are not limited to: WINDOWS 2000, WINDOWS Server 2012, WINDOWS CE, WINDOWS Phone, WINDOWS XP, WINDOWS VISTA, and WINDOWS 7, WINDOWS RT, and WINDOWS 8 all of which are manufactured by Microsoft Corporation of Redmond, Wash.; MAC OS and iOS, manufactured by Apple, Inc. of Cupertino, Calif.; and Linux, a freely-available operating system, e.g. Linux Mint distribution (“distro”) or Ubuntu, distributed by Canonical Ltd. of London, United Kingdom; or Unix or other Unix-like derivative operating systems; and Android, designed by Google, of Mountain View, Calif., among others. Some operating systems, including, e.g., the CHROME OS by Google, can be used on zero clients or thin clients, including, e.g., CHROMEBOOKS.

The computer system 200 can be any workstation, telephone, desktop computer, laptop or notebook computer, netbook, ULTRABOOK, tablet, server, handheld computer, mobile telephone, smartphone or other portable telecommunications device, media playing device, a gaming system, mobile computing device, or any other type and/or form of computing, telecommunications or media device that is capable of communication. The computer system 200 has sufficient processor power and memory capacity to perform the operations described herein. In some embodiments, the computing device 200 can have different processors, operating systems, and input devices consistent with the device. The Samsung GALAXY smartphones, e.g., operate under the control of Android operating system developed by Google, Inc. GALAXY smartphones receive input via a touch interface.

In some embodiments, the computing device 200 is a gaming system. For example, the computer system 200 can comprise a PLAYSTATION 3, or PERSONAL PLAYSTATION PORTABLE (PSP), or a PLAYSTATION VITA device manufactured by the Sony Corporation of Tokyo, Japan, a NINTENDO DS, NINTENDO 3DS, NINTENDO WIT, or a NINTENDO WIT U device manufactured by Nintendo Co., Ltd., of Kyoto, Japan, an XBOX 360 device manufactured by the Microsoft Corporation of Redmond, Wash.

In some embodiments, the computing device 200 is a digital audio player such as the Apple IPOD, IPOD Touch, and IPOD NANO lines of devices, manufactured by Apple Computer of Cupertino, Calif. Some digital audio players can have other functionality, including, e.g., a gaming system or any functionality made available by an application from a digital application distribution platform. For example, the IPOD Touch can access the Apple App Store. In some embodiments, the computing device 200 is a portable media player or digital audio player supporting file formats including, but not limited to, MP3, WAV, M4A/AAC, WMA Protected AAC, AIFF, Audible audiobook, Apple Lossless audio file formats and .mov, .m4v, and .mp4 MPEG-4 (H.264/MPEG-4 AVC) video file formats.

In some embodiments, the computing device 200 is a tablet e.g. the IPAD line of devices by Apple; GALAXY TAB family of devices by Samsung; or KINDLE FIRE, by Amazon.com, Inc. of Seattle, Wash. In other embodiments, the computing device 200 is an eBook reader, e.g. the KINDLE family of devices by Amazon.com, or NOOK family of devices by Barnes & Noble, Inc. of New York City, N.Y.

In some embodiments, the communications device 200 includes a combination of devices, e.g. a smartphone combined with a digital audio player or portable media player. For example, one of these embodiments is a smartphone, e.g. the IPHONE family of smartphones manufactured by Apple, Inc.; a Samsung GALAXY family of smartphones manufactured by Samsung, Inc; or a Motorola DROID family of smartphones. In yet another embodiment, the communications device 200 is a laptop or desktop computer equipped with a web browser and a microphone and speaker system, e.g. a telephony headset. In these embodiments, the communications devices 200 are web-enabled and can receive and initiate phone calls. In some embodiments, a laptop or desktop computer is also equipped with a webcam or other video capture device that enables video chat and video call.

In some embodiments, the status of one or more machines 200 in the network 140 are monitored, generally as part of network management. In one of these embodiments, the status of a machine can include an identification of load information (e.g., the number of processes on the machine, CPU and memory utilization), of port information (e.g., the number of available communication ports and the port addresses), or of session status (e.g., the duration and type of processes, and whether a process is active or idle). In another of these embodiments, this information can be identified by a plurality of metrics, and the plurality of metrics can be applied at least in part towards decisions in load distribution, network traffic management, and network failure recovery as well as any aspects of operations of the present solution described herein. Aspects of the operating environments and components described above will become apparent in the context of the systems and methods disclosed herein.

C. Measuring and Processing Voltage Signals to Regulate a Voltage Tap Setting

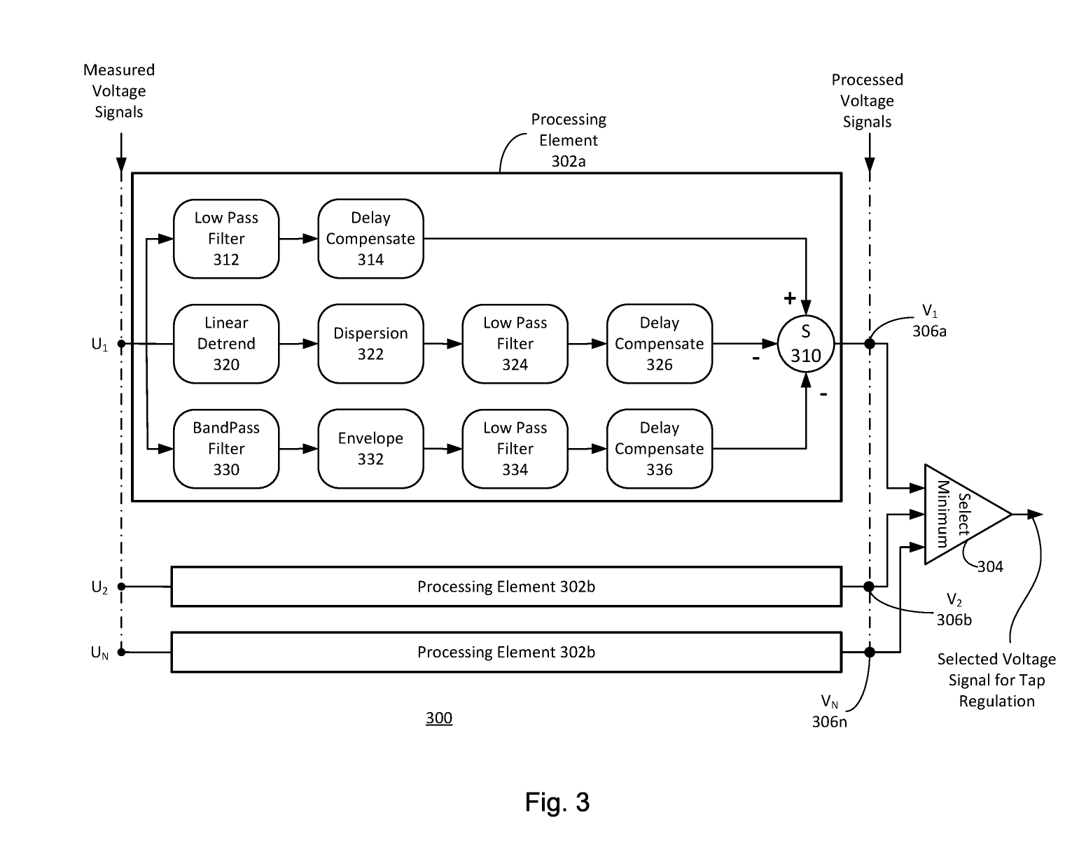

Referring to FIG. 3, voltage signal processing element 300 is shown having processing elements 302a-302n coupled to minimum selector circuit 304. Each of the processing elements 302a-302n receives on their respective input terminals a measured voltage signal from a respective metering device 118a-118n (FIG. 1). Processing elements 302a-302n processes the measured signal (as described herein) and generates a processed voltage signal on their output terminals 306a-306n respectively. Minimum selector circuit 304 selects the processed voltage signal having the minimum voltage and provides the selected signal to the voltage adjustment decision processor circuit 128 for further processing in tap setting regulation. In some embodiments, the processed voltage signals 306a can be further processed or processed using the voltage estimator 220 to generate a forecasted secondary voltage drop.

In some embodiments, the processing element 302 processes primary signals such that the primary signals can be available on a same basis as the AMI secondary signals. The processing element 302 can perform a smoothing technique to preserve interval means. This smoothing technique can not be a real-time technique. The processing element 302 can be configured with one or more smoothing technique. For example, in a first smoothing technique, the processing element 302 can compute (or determine or generate) a means over fixed intervals of interest. This technique can be used if the observations are symmetrically distributed (e.g., a Gaussian distribution). In another example, in a second smoothing technique, the processing element 302 can compute a symmetrical odd integer length polynomial window. This processing element 302 can determine, generate or estimate the polynomial window to minimize or reduce a mean-squared error of the polynomial fit on each interval. To do this, the processing element 302 can be configured with a Savitzky-Golay digital filter that can be applied to the observations to smooth the data (e.g., increase signal-to-noise ratio) without greatly distorting the signal by preserving the mean over the interval of interest. This digital filter can be configured with a convolution technique that fits successive sub-sets of adjacent data points with a low-degree polynomial using linear least squares. When the data points are equally or substantially equally (e.g., plus or minus 10%) spaced, the processing element 302 can determine, generate or identify an analytical solution to the least-squares equations. The analytical solution can be in the form of a set of “convolution coefficients” that can be applied to all data sub-sets, to give estimates of the smoothed signal, (or derivatives of the smoothed signal) at the central point of each sub-set.

In yet another example, in a third filtering technique, the processing element 302 can apply a net zero group delay low pass filter to the signal having a cutoff consistent with the sampling rate of the AMI measurements. To do this, the processing element 302 can be configured with forward and reverse convolution circuits or processor. In another example, in a fourth smoothing technique, the processing element 300 can be configured with a causal finite impulse response (“FIR”) filter, such as a Wiener filter. The processing element 302, configured with a FIR Wiener filter, can produce an estimate of a desired or target random process by linear time-invariant (LTI) filtering of an observed noisy process, assuming known stationary signal and noise spectra, and additive noise. The Wiener filter can reduce or minimize a mean square error between the estimated random process and the desired process. In yet another example, in a fifth smoothing technique, the processing element 302 can be configured with minimum variance smoothing or a Kalman filter. The processing element 302, configured with this technique, can use the series of measurements observed over time to produce estimates of unknown variables.

Still referring to FIG. 3, and in further detail, processing elements 302a-302n can be the same or include the same functionality or configuration. Processing element 302a can include three parallel or overlapping processing paths that are coupled to summation circuit 310. Each of the processing elements receives sampled time series signals from metering devices 118a-118n.

In the first path, a low pass filter circuit 312 receives the measured voltage signal, applies a low pass filter to the signal and feeds the low pass filtered signal to delay compensate circuit 314 where the signal or an estimate of the signal is extrapolated in time such that the delay resulting from the low pass filtering operation is removed and then fed to summation circuit 310.

In the second path, a linear detrend circuit 320 receives the measured voltage signal, and removes any linear trends from the signal. The resulting signal, having zero mean and being devoid of any change in its average value over its duration, is then applied to dispersion circuit 322 where a zero mean dispersion is estimated for the signal. The zero mean dispersion estimated signal is fed to low pass filter circuit 324 that applies a low pass filter to the signal. The filtered signal is then fed to delay compensation circuit 326 where the filtered signal or an estimate of the filtered signal is extrapolated in time such that the delay resulting from the low pass filtering operation is removed. The filtered, extrapolated signal can then also fed to the summation circuit.

In the third path, a band pass filter circuit 330 receives the measured voltage signal, and applies a band pass filter to the signal. The filtered signal is then applied to an envelope circuit 332 where the signal is formed into a peak envelope with specified peak decay characteristics. The peak envelope signal is fed to low pass filter circuit 334 that applies a low pass filter to the signal to provide a filtered smooth peak envelope voltage signal, and feeds the signal to delay compensation circuit 336 where the filtered smooth peak envelope voltage signal or an estimate thereof is extrapolated in time such that the delay resulting from the low pass filtering operation is removed before being fed to as a delay compensated signal to summation circuit 310. Summing the plural signal processing paths can facilitate extracting information of interest from the input signal, and produce this information in the form of a derived signal configured for consumption by the decision processes. By summing multiple signal processing paths, the system can extract information from the input signal to produce this information in a form of a derived signal suitable for processing by the decision process.

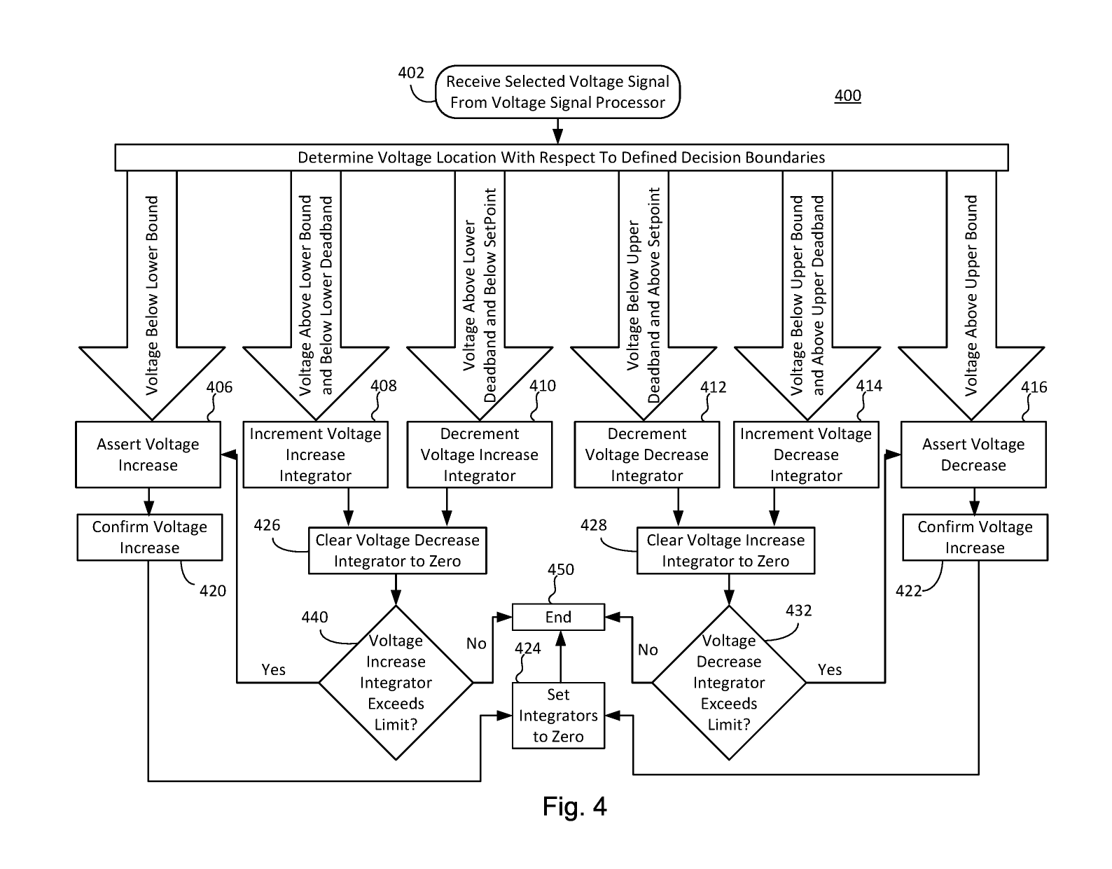

Illustrated in FIG. 4, is a process 400 for determining a voltage adjustment decision. The exemplary process in FIG. 4 is illustrated as a collection of blocks in a logical flow diagram, which represents a sequence of operations that can be implemented in hardware, software, and a combination thereof. In the context of software, the blocks represent computer-executable instructions that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described blocks can be combined in any order and/or in parallel to implement the process. For discussion purposes, the processes are described with reference to FIG. 4, although it can be implemented in other system architectures.

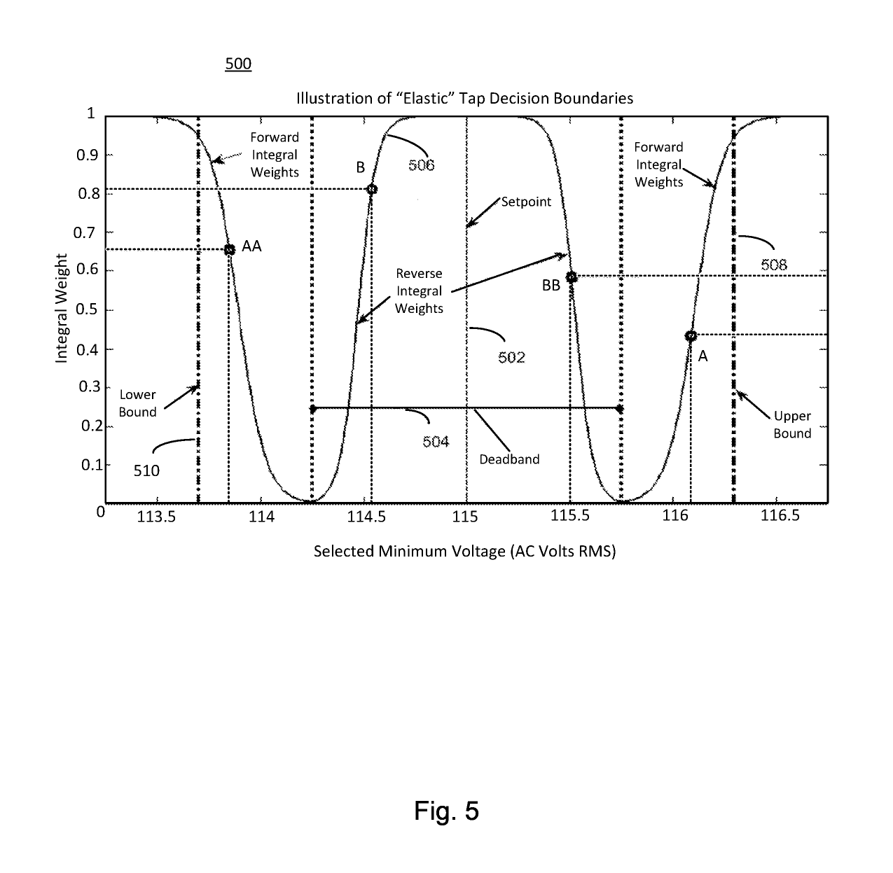

Referring to FIG. 4, a process 400 is shown for determining a voltage adjustment decision by voltage adjustment decision processor circuit 128 using the processor and modules shown in FIG. 3. In the process, at block 402, the selected voltage signal is received from the voltage signal processing element 200 (FIG. 2) from block 304. In block 404, a determination is made of the location of the voltage with respect to defined boundary decisions. A graph of exemplary voltage locations and their boundaries is shown in FIG. 5. The graph can be stored in a data structure as values or in a delimited format that facilities retrieval of the graph information to determine a tap decision. The decision boundaries were preset based on characteristics of the electrical and electronic devices comprising the loads and confidence levels as discussed herein.

If a determination is made that the received selected voltage is below a lower boundary, an assert voltage increase is executed in block 406. When a voltage increase assertion is executed an increase indication signal is sent to voltage regulating transformer 106 via the regulator interface 110 to increase the tap setting, thereby increasing the delivered voltage.

If a determination is made that the received selected voltage is above the lower bound and below the lower deadband, an increment voltage increase integrator is executed in block 408. If a determination is made that the received selected voltage is above the lower deadband and below the setpoint, a decrement voltage increase integrator is executed in block 410.

If a determination is made that the received selected voltage is below the upper deadband and above the setpoint, a decrement voltage increase integrator is executed in block 412. If a determination is made that the received selected voltage is below the upper bound and above the upper dead band, an increment voltage decrease integrator is executed in block 414.

If a determination is made that the received selected voltage is about the upper bound, an assert voltage decrease is executed in block 416. When an assert voltage decrease is executed a decrease indication signal is sent to voltage regulator transformer via the regulator interface 110 to decrease the tap voltage.

After the assert voltage increase is executed in block 406, a confirm voltage increase is executed in block 420. After the assert voltage decrease is executed in block 416, a confirm voltage decrease is executed in block 422. After executing the confirm voltage increase in block 420 and confirm voltage decrease in block 422, a set all integrators to zero is executed in block 424.

After executing the increment voltage increase integrator in block 408 and the decrement voltage increase integrator in block 410, a set voltage decrease integrator to a zero is executed in block 426. After executing the decrement voltage decrease integrator in block 412 and the increment voltage decrease integrator in block 414, a set voltage increase integrator to a zero is executed in block 428.

After executing set voltage decrease integrator to zero is executed in block 426, a determination is made in block 440 whether the voltage increase integrator exceeds a predetermined limit. If the voltage increase integrator exceeds the predetermined limit, then a voltage increase is asserted in block 406 and confirmed in block 420. If the voltage increase integrator does not exceed the predetermined limit, then the process ends in block 450.

After executing set voltage increase integrator to zero is executed in block 428, a determination is made in block 432 whether the voltage decrease integrator exceeds a predetermined limit. If the voltage increase integrator exceeds the predetermined limit, then a voltage decrease is asserted in block 416 and confirmed in block 422. If the voltage decrease integrator does not exceed the predetermined limit, then the process ends in block 450.

Confirmation of a voltage increase or decrease can be implemented by detecting a step change in one or more voltage(s) measured by corresponding metering device(s) 118a-118n. An exemplary method for detection of such a step change involves computation of the statistical moments of a voltage time series segment which is expected to manifest a step change, and comparing those moments with those for an ideal step change such as the Heaviside step function. In this method of moment matching, the magnitude of the computed step change can be compared to that expected by the change in the voltage regulator tap setting to confirm that the voltage change has occurred.

Once the voltages are confirmed in blocks 420 and 422 all integrators are set to zero in block 424 and the process ends in bock 450.

If the voltage decrease integrator does not exceed the predetermined limit, and after setting all integrators to zero in block 448, the process ends in block 450. After ending in block 450 the process can repeat again upon receiving the selected signal from the voltage processor in block 402.

Referring to FIG. 5, there is shown graph 500 illustrating exemplary elastic tap decision boundaries used by the process described in FIG. 4. On the x-axis of graph 500 are the salient voltages and on the y-axis is shown selected integral weights assigned to the voltage regions. A set point voltage 502 is indicated at the center voltage level, and a deadband 504 is assigned at equal voltage displacements from the set point voltage.

An upper bound 508 and lower bound 510 are outside the deadband and are defined based on the predetermined confidence level using the formulas described herein. The forward integration regions are defined as the region between the deadband and the upper bound, or between the deadband and the lower bound. The forward integral weights are applied in these regions. The reverse integration regions are defined as the regions between the dead band and the set point voltage 502.

The system can adjust a tap setting responsive to voltage changes on curved decision boundaries. In one embodiment when the received selected voltage signal from the voltage processor is at a selected minimum voltage at Point “A”, the nonlinear integral associated with a tap decrease decision will be incremented. If the received selected voltage signal remains within the indicated region, eventually a voltage tap decrease will be asserted. Similarly, when the selected minimum voltage appears at Point “AA”, the nonlinear integral associated with a tap increase decision will be incremented, eventually resulting in a voltage tap increase assertion.

On the other hand if when the received selected voltage signal from the voltage processor is at a selected minimum voltage at Point “B”, the nonlinear integral associated with a tap increase decision will be decremented and eventually nullifying the pending tap decision. Similarly, when the selected minimum voltage appears at Point “BB”, the nonlinear integral associated with a tap decrease decision will be decremented, eventually nullifying the pending tap decision.

The system can use the following techniques to determine dispersion and variance. For a subject time series obtained by uniform sampling of a random process, comprising sample values:

xₖ, 1≦k≦n, one can estimate the scale of the sampled time series as either the sample variance or the sample dispersion, depending on the properties of the random process from which the samples are obtained.

First, an estimate of the statistical location, often referred to as the average or mean, is required. For some non-gaussian random processes, the sample mean does not suffice for this purpose, motivating the use of the median or other robust measures of sample location. In the formulas that follow, we shall designate the location estimate as x̅.

A class of non-gaussian random processes is characterized by heavy-tailed probability densities, which are often modeled for analytical purposes as alpha-stable distributions and are thus referred to as alpha-stable random processes. For time series sampled from non-gaussian alpha-stable random processes, one can estimate the scale as the sample dispersion:

$$d = {e}^{\frac{1}{n} {\sum }_{k = 1}^{n} ln \vert {x}_{k} - \overline{x} \vert} , \\ for$$

$${x}_{k} \neq \overline{x}$$

For time series sampled from Gaussian random processes, one can estimate the scale as the sample variance:

$$s = \frac{1}{n - 1} {\sum }_{k = 1}^{n} {( {x}_{k} - \overline{x} )}^{2}$$

The choice of the location and scale estimates can be motivated by the properties of the subject random process, which can be determined, for example, by examination of estimates of the probability density of the random process.

The voltage controller 108 can use one or more weighting factors and integration formulas to identify a deviation voltage used to make a decision. In some embodiments, the deviation voltage can be based on an estimated secondary voltage drop or forecasted secondary voltage drop as determined by the voltage estimator 220. In some embodiments, the deviation voltage used in the decision boundary integrals can be computed as the difference between the selected minimum voltage and the voltage setpoint:

Δv=vₘᵢₙ−vₛₑₜ

The computation of the weighting factors requires that the parameters for the weighting functions be defined and available to the voltage controller processor. The following example will use the first-order sigmoid function as the nonlinear weighting function but many others can be applied to achieve different integrating behavior; for example, trigonometric functions, linear or trapezoidal functions, polynomial functions, spine fitting functions, or exponential functions of any order could serve here. In the following definitions, specific subscripts will be used to denote the region of application of the defined quantity as follows:

subscript a can indicate the region above the setpoint voltage vₛₑₜ;

subscript b can indicate the region below the setpoint voltage vₛₑₜ;

subscript f can indicate quantities used in the forward (incrementing) integrals;

subscript r can indicate quantities used in the reverse (decrementing) integrals;

v_{af} and v_{bf} can be defined as the inflection points of the sigmoid functions for the weights for the upper (voltage decrease) and lower (voltage increase) forward integrals, respectively;

vₐᵣ and v_{br} are inflection points of the sigmoid functions for the weights for the upper (voltage decrease) and lower (voltage increase) reverse integrals, respectively.

2Δv_{d} are the magnitude of the voltage deadband, symmetrical around the voltage setpoint.

Assigning the quantity β as the slope parameter for the first-order sigmoid and the quantity ω as the voltage corresponding to the location of the inflection point, the nonlinear weighting functions for the four regions of interest can be determined using the following equations:)

ω_{af}=[1+e^{β}^{_{af}}^{(v}^{_{af}}^{-v}^{ₘᵢₙ}⁾]⁻¹ is the upper forward integral weight function

ωₐᵣ=[1+e^{β}^{ₐᵣ}^{(v}^{ₘᵢₙ}^{-v}^{ₐᵣ}⁾]⁻¹ is the upper reverse integral weight function

ω_{bf}=[1+e^{β}^{_{bf}}^{(v}^{ₘᵢₙ}^{-v}^{_{bf}}⁾]⁻¹ is the lower forward integral weight function

ω_{br}=[1+e^{β}^{_{br}}^{(v}^{_{af}}^{-v}^{ₘᵢₙ}⁾]⁻¹ is the lower reverse integral weight function

The upper voltage adjustment decision integral can now be written as

$${Ψ}_{a} = \frac{1}{{T}_{a}} \int ( {w}_{af} Δ v {{\vert}_{Δ v > {v}_{set} + {v}_{d}} - {w}_{ar} Δ v \vert}_{Δ v < {v}_{set} + {v}_{d}} ) d t$$

and the lower voltage adjustment decision integral as

$${Ψ}_{b} = - \frac{1}{{T}_{b}} \int ( {w}_{bf} Δ v {{\vert}_{Δ v < {v}_{set} + {v}_{d}} - {w}_{br} Δ v \vert}_{Δ v > {v}_{set} - {v}_{d}} ) d t$$

The voltage controller then asserts a voltage decrease signal (causing the voltage regulating transformer 106 to tap down) if either

Δv>vₐ−vₛₑₜ OR Ψₐ>vₐ−vₛₑₜ

in either case, the controller further determines that the “tap down} operation will not cause the voltage regulating transformer 106 to exceed the lowest tap position permitted by the regulator interface device.

Similarly, the voltage controller then asserts a voltage increase signal (causing the voltage regulating transformer 106 to tap up) if either

Δv<v_{b}−vₛₑₜ OR Ψ_{b}<v_{b}−vₛₑₜ

in either case, the controller further determines that the ‘tap up’ operation will not cause the voltage regulating transformer 106 to exceed the highest tap position permitted by the regulator interface device.

D. Systems and Methods of Estimating Secondary Voltage Loss

The present disclosure is directed towards systems and methods of estimating a characteristic of electricity at a location in a utility grid. More specifically, the present disclosure can facilitate estimating a secondary voltage drop at a customer site using advanced metering infrastructure (“AMI”) of the utility grid. The AMI system provides information about the electricity supplied from a power source to a customer sites. Since the amount or type of information provided by AMI systems can vary based on a type of AMI metering device, or configuration or operation of the AMI system, the present disclosure can facilitate estimating the characteristic of electricity using a minimal signal complement obtained via AMI systems. The minimal signal complement can refer to less than complete information provided by an AMI system. For example, the minimal signal complement can refer to physical observations in a given interval that are (a) unsuitable for statistically satisfactory estimates, or (b) incomplete with respect to physical quantities of interest in the characterization of consumer energy demand processes, or both.

In some embodiments, systems and methods of the present disclosure are directed to identifying, determining, or estimating a secondary voltage drop for customer sites equipped with responsive AMI devices. The present disclosure can be configured with a technique that is designed to operate with a minimal signal complement available in AMI systems. For example, AMI site observations can be sampled at nominally uniform intervals such that a number of sampling intervals in a demand cycle is a positive integer. During the sampling interval, the system can generate AMI sample records. However, the AMI sample records can include defects. These defects can include missing observations, incomplete observations, an observation that fails a quality check, or an otherwise void observation. Quality check can include a time interval between observation samples, a value of the observation satisfying a threshold (e.g., less than or equal to a threshold, or greater than or equal to a threshold), etc. Since the void observations are due to defects, a probability of occurrence of the void observations can be unknown.

The observed or measured quantities can be discrete-time sampled. The measurements can, in some examples, be interpreted as zero-order-hold sequences. For example, the system can include or be configured with circuitry or one or more processors designed and constructed to convert a discrete-time sampled signal to a continuous-time signal by holding each sample value for a sample interval. An AMI site observation can include samples of one or more signals related to the sites terminal conditions at the time of samples. For example, a first signal related to the site terminal conditions can include a delivered secondary voltage, single known phase, with RMS basis volts. A second signal related to the site terminal conditions can include a real demand, also single known phase, in actual Watts. The second signal can also correspond to or indicate a power factor. In another example, the signals can include interval observations such as a first signal corresponding to an interval secondary location, single known phase, RMS basis volts, in which the location estimator is the unweighted mean of uniformly sampled observations at a sampling rate determined by the metering instrument. Further to this example, the second signal can include or indicate an interval energy consumption, single known phase, in actual watt-seconds or other proportional unit (e.g., Watt-hour or Kilowatt-hour).

The AMI observation or sample records can be stored in an AMI sample data structure or database. The AMI observations records can be organized as sets or ensembles of time series, such that each set or ensemble member includes a time series of observations for a predetermined time interval (e.g., a 24 hour time series). The overall sets or ensemble extent can be limited or bounded by a predetermined history duration (e.g., 30 days).

The present solution can determine, detect, or otherwise identify a void, defective, or missing observation in one or more sample records (or sets or ensembles) during one or more sampling intervals or demand intervals. With this information, the present solution can generate void-compensated historical weights and apply these weights to determine a secondary voltage drop.

Since these AMI observations or sample records can include defective observation time series that include voids, the present solution can apply historical sample weights unique or tailored to each AMI demand interval. The present solution can assign a predetermined weight (e.g., zero “0”, 0.01, 0.0001, 0.1, 1, etc.) to a void sample. Assigning or setting a zero weight to void samples, for example, can modify a weighting profile for the available samples. The system can be configured to determine the weighting profile using one or more weighting techniques. The weighting techniques can be based on a number of void samples in a particular time series or sample record, or a total number or aggregate number of voids in the entire ensemble (e.g., the predetermined history duration). For example, the system can use one or more of the following weighting techniques: (1) uniformly weight the observation history for each AMI demand interval; (2) compute an intended historical weight profile with the assumption that all samples are available, and then assign zero weight to void samples, and then scale the remaining weights applied to available samples such that a sum of the applied weights is unity; or (3) compute an intended historical weight profile assuming all samples are available, assign zero weight to void samples, and then distribute the previously voided weight to the adjacent available samples.

To estimate the secondary voltage drop, the system can use measurements obtained from substation metering, regulation site metering, and AMI device site metering. The system can use the secondary voltage drop estimates to adjust a voltage setpoint that adapts the primary voltage setpoints (e.g., as illustrated in FIG. 5). Thus, the system, in some embodiments, can use a deviant voltage to determine the voltage setpoints or use a forecasted or estimated secondary voltage drop to determine the voltage setpoints, lower and upper bounds, or deadband.

As illustrated in FIG. 1, the substation, regulation site, and AMI device site can correspond to different points in a distribution or utility grid. For example, the substation metering can include measurements indicative of per-phase voltage or per-phase power obtained at or near substation 104. The regulation site metering can include measurements indicative of per-phase voltage or per-phase power at or near a voltage regulating transformer 106a-b. The AMI device site metering can include measurements indicative of delivered voltage or interval power at one or more metering devices 118a-n.

As illustrated in FIG. 1, a single primary distribution circuit 112 can drive multiple secondary utilization circuits 116. The association of an AMI device to a controllable primary circuit segment can be known a priori. The system can process the measurements obtained from one or more points in the utility grid to determine the secondary voltage drop. In some embodiments, the system can apply signal processing to filter and resample the primary signals (e.g., measurements of characteristics of electricity obtained from points on the primary distribution circuit 112 of the utility grid) such that the signals are available on a same or similar basis as the AMI secondary signals (e.g., measurements of characteristics of electricity obtained from points on the secondary utilization circuit 116).

Upon filtering and processing the signals from the primary and secondary circuits such that they are available on a similar basis, the system can estimate one or more parameters or metrics associated with the signals. In some embodiments, the system can apply one or more weighting techniques and a historical analysis to determine the secondary voltage drop. For example, the system can estimate the secondary voltage drop using 30 days' worth of metering history. The system can weight the samples based on when they occurred to generate an estimate for the secondary voltage drop.

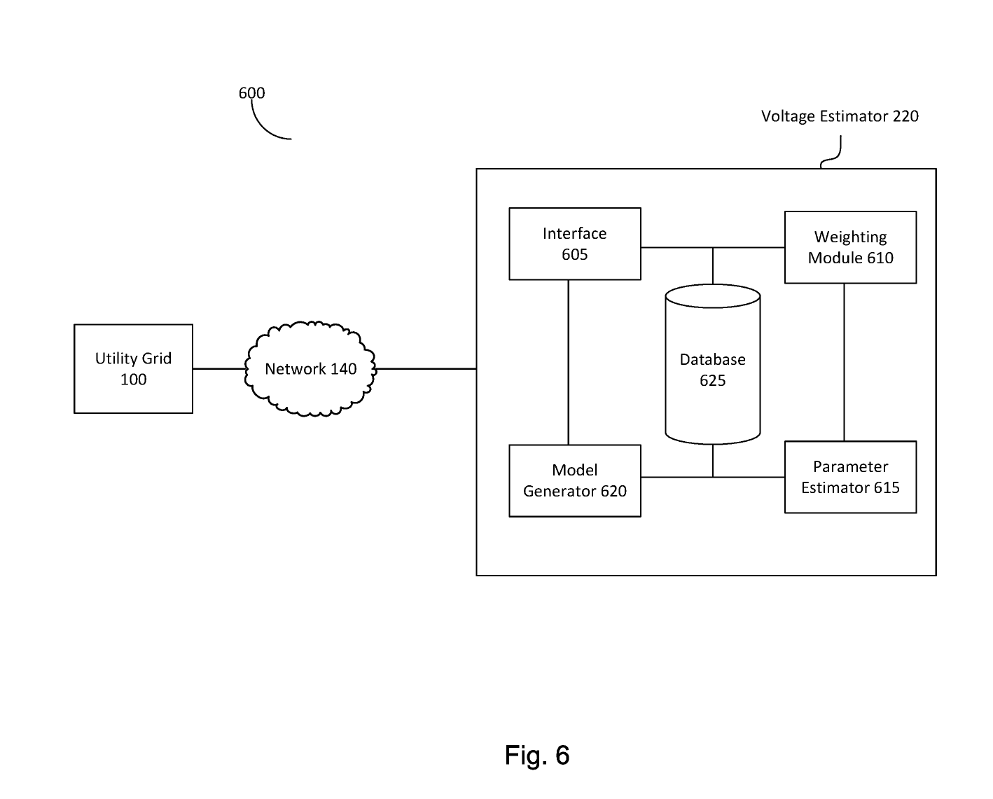

Referring now to FIG. 6, a bock diagram depicting a system for estimating a secondary voltage drop with minimal signal complement in a utility grid in accordance with an embodiment is shown. In brief overview, the system 600 includes a voltage estimator 220, a network 140, and a utility grid 100. The voltage estimator 220 can include an interface 605 component that receives information about characteristics of electricity associated with utility grid 100 and output information such as processed information or control signals. The voltage estimator 220 can include a weighting module or component 610 that identifies, detects or determines voids or defective observations and generates or applies a weight using one or more weighting techniques. The voltage estimator 220 can include a parameter estimator component 615 that processes signals or measurements obtained from one or more points or locations in a utility grid to estimate characteristics of electricity. The voltage estimator 220 can include a model generator component 620 that generates, identifies or determines a characteristic of electricity, such as a secondary voltage drop.

The system 600, voltage estimator 220, network 140, or utility grid 100, or one or more component thereof, can include one or more component, module, or functionality illustrated or described in relation to FIGS. 1-4. For example, voltage estimator 220 can include one or more component or functionality of voltage controller 108, regulator interface 110, processing element 302 or system 300, or flow diagram 400.

In some embodiments, the voltage estimator 220 can obtain measurements from the utility grid 100 via network 140, generate an estimate for a characteristic of electricity, and provide the estimate for the characteristic to a component of the utility grid 100 (e.g., voltage controller 108) via network 140. In some embodiments, the voltage estimator 220 is configured to estimate a secondary voltage drop.

In further detail, interface 605 can be designed and constructed to obtain information about characteristics of electricity. The information can include, e.g., voltage, current, power, impedance, inductance, capacitance, reactive power, apparent power, or power factor. The information can also include environmental information such as ambient temperature, meteorological information (e.g., weather forecast), historical weather information, statistical information regarding electrical consumption, etc. The interface 605 can obtain or receive samples of characteristics of electricity from metering devices 118, substation 104, regulation transformer 106a-b, distribution point 114 or any other point in the utility grid 100.

In some embodiments, the voltage estimator 220 can obtain signals corresponding to a per-phase voltage and per-phase power from substation metering (e.g., 104), per-phase voltage and per-phase power from regulation site metering (e.g., 106a-b, 112, or 114), and delivered voltage and interval power from AMI device site metering (e.g., 118a-n). In some embodiments, the voltage estimator 220 can use additional signals such as ambient temperature obtained from proximal meteorological stations or ambient temperature from other measurement devices proximate to the utility that are configured with telemetry functionality or can communicate temperature information via network 140.

The measurements or quantities observed or computed by the voltage estimator 220 can be discrete time sampled and interpreted as zero-order-hold sequences. In some embodiments, an AMI site observation can include samples of two signals related to the site terminal conditions at the time of sampling: (1) delivered secondary voltage, single known phase, RMS basis volts; and (2) real demand, single known phase, actual watts. The real demand can include power factor information. In some embodiments, AMI site observations can include interval observations such that: (1) interval secondary voltage location, single known phase, RMS basis volts, in which the location estimator corresponds to an unweighted mean of uniformly sampled observations at a sampling rate determined by the metering instrument (e.g., metering device 118a); and (2) interval energy consumption, single known phase, actual watt-seconds or other proportional unit (e.g., Watt-hour or Kilowatt-hour). The sample interval can be the same or similar to the demand interval. Further, the AMI site observations can be sampled at nominally uniform intervals such that a number of sample intervals in demand cycle is a positive integer and the demand cycle is a predetermined time interval (e.g., 12 hours, 24 hours, 48 hours, 72 hours, etc.).

The AMI measurements or observations can be stored in a database or data structure. For example, the AMI measurements can be stored or organized as a plurality of sets of time series observations. A first time series set of the plurality of sets of time series can include a time series for a predetermined time interval, such as a 24-hour time series. A second time series in the plurality of sets of time series can include a second 24-hour time series. The plurality of sets of time series can correspond to a predetermined history duration, such as 7 days, 14 days, 30 days, 60 days, etc. In some cases, one or more sets of the plurality of sets of time series can include defects. These defects can manifest as missing or otherwise void observations. For example, one or more sets in the plurality of sets of time series can include one or more defects or voids. Due to the nature of the defects or voids, the probability of occurrence of the defects or voids can be unknown.

In some embodiments, the information obtained by the voltage estimator 220 can be pre-processed. For example, processing element 302 can obtain measured voltage signals from one or more components in the utility grid 100, process the measurements, and then provide the processed signals 306 to the voltage estimator 220.

The voltage estimator 220 can include a weighting module 610 (or weighting circuit 610 or weighting engine 610) designed and constructed to generate or apply weights using one or more weighting techniques. In some embodiments, the weighting module 610 generates historical weights using the following function:

w(h)=[1+e^{β(h-1-H/2)/H}]⁻¹, for 1≦h≦H Equation 1: Reference Historical weights

In this equation, h refers to a duration of signal history, in days, where h=0 is the present day; H refers to the maximum duration of the signal history in days; β is a sigmoid inflection slope for historical weights; and w(h) represents the initial historical weights. The sigmoid inflection slope for historical weights β can be adjusted or optimized using various techniques. In some embodiments, the initial value for β can be 5, 3, 6, 10 or some other value that facilities applying a weight to determine, estimate, or forecast a secondary voltage drop.

In some embodiments, the voltage estimator 220 (e.g., via weighting module 610) can determine, detect, or otherwise identify a void, defective, or missing observation in one or more sample records (or sets or ensembles) during one or more sampling intervals or demand intervals. For example, the voltage estimator 220 can identify a missing observation by monitoring time stamps associated with observations to determine that, based on a sampling rate, an expected sample is not found. For example, a sample rate can be 1 Hz. Based on this sample rate, the voltage estimator 220 can expect to identify 60 samples in a minute. However, the voltage estimator 220 can only identify 55 samples in the minute. Thus, the voltage estimator 220 can determine there are 5 void or missing samples. The voltage estimator 220 can further determine, based on time stamps of the valid samples, an order for the void sample. For example, the set of samples (or time series set) can include a first sample that is valid, a second sample that is valid, and a third sample that is invalid. Thus, the voltage estimator 220 can flag, mark, or other indicate that the third sample in the time series is invalid or a void sample.

Since these AMI observations can include defective sets that include voids, the voltage estimator 220 (e.g., via weighting module 610) can apply historical sample weights unique or tailored to each AMI demand interval. The weighting module 610 can assign a predetermined weight (e.g., zero “0”, 0.01, 0.0001, 0.1, 1, etc.) to a void sample. Assigning or setting a zero weight to void samples, for example, can modify a weighting profile for the available samples. The system can be configured to determine the weighting profile using one or more weighting techniques. The weighting techniques can be based on a number of void samples in a particular time series or sample record, or a total number or aggregate number of voids in the entire ensemble (e.g., the predetermined history duration). For example, the system can use one or more of the following weighting techniques: (1) uniformly weight the observation history for each AMI demand interval; (2) compute an intended historical weight profile with the assumption that all samples are available, and then assign zero weight to void samples, and then scale the remaining weights applied to available samples such that a sum of the applied weights is unity; or (3) compute an intended historical weight profile assuming all samples are available, assign zero weight to void samples, and then distribute the previously voided weight to the adjacent available samples.

For example, the voltage estimator 220 can determine, assign, or set the weights as follows to determine void-compensated historical weights.

wₖ(n,h)=w(h), for 1≦n≦N, 1≦k≦K initial weights Equation 2: Weight for valid samples.

wₖ(n,h)=0, for void observation vₖ(n,h), or pₖ(n,h) Equation 3: For invalid or void samples.

In example Equation 3, the void observations are set to zero. The weight can be set to zero responsive to the voltage estimator determining that an observation corresponding to a secondary basis voltage signal vₖ (n, h) is missing or defective. The voltage estimator can also set the weight to zero if the observation corresponding to a secondary real demand signal pₖ(n,h) is missing or defective. The weighting module 610 can combine the weights for valid samples and void samples to generate void-compensated historical weights w_{c}(n,h).

The weighting module 610 can provide the historical weights to one or more module or component of system 600. In some embodiments, the weighting module 610 can store the weights in a database 625 or memory or storage device such that one or more module or component of voltage estimator 220 can obtain or retrieve the weights to apply the weights. For example, the weights can be predetermined or precomputed in an offline manner, and stored in a data structure of data file (e.g., in a delimited format, comma separated format, etc.) for later retrieval and processing.

In some embodiments, the system 600 includes a parameter estimator 615 designed and constructed to determine, identify, or estimate on or more parameter related to a characteristic of electricity. In some embodiments, the parameter estimator can determine a real demand ratio based on the historical weights and a primary real demand; a site correlated primary basis voltage; and an estimated secondary impedance. In some embodiments, the parameter estimator 615 can be further configured to determine one or more boundary or setting used to control a voltage level. For example, the parameters or values determined by the parameter estimator 615 can include a voltage boundary (e.g., a primary voltage lower bound) used to control a voltage tap setting.

To determine an estimated real demand ratio, the voltage estimator 220 can obtain or determine a secondary real demand and a primary real demand. The secondary real demand can refer to characteristics of electricity (e.g., power in watts, voltage in volts, or current in amperes) at a location in the secondary utilization circuit 116 (e.g., as obtained by a metering device 118a). The real demand ratio can be determined on a per-sample index and a per-metering site index basis. For example, the voltage estimator 220 can determine a real demand ratio for a specific metering site (e.g., metering site 118a) for a specific sample during a given day by taking the ratio of a measurement sample indicative of a secondary real demand as measured by the metering device 118a and a corresponding measurement sample of a primary real demand as measured at a point in the primary distribution circuit 112 (e.g., sample index can be correlated based on time or other correlation technique).

The parameter estimator 220 can further determine a site correlated primary basis voltage. This site correlated primary basis voltage can be determined on a per site basis and based on a partial or full history of samples. The site can refer to a consumer site or some other site on the secondary utilization circuit that can correspond to or include a metering device 118a-n. In some embodiments, the primary basis voltage can refer to the voltage on a primary coil of transformer 120a-n that corresponds to a metering device 118a-n. The parameter estimator 220 can apply a historical weight to a primary basis voltage measurement to generate, determine, or estimate the site correlated primary basis voltage.

In some embodiments, the parameter estimator 220 identifies, determines, or estimates a first secondary impedance. This first secondary impedance can refer to a secondary impedance that is determined based on analyzing historical samples. The secondary impedance can be determined on a per site basis and based on a partial or full history of samples.

The voltage estimator 220 can determine the first secondary impedance based on a difference between a primary basis voltage and a secondary basis voltage. The primary basis voltage can refer to a voltage measured at a point in the primary distribution circuit 112 or at a primary coil in transformer 120a-n. The secondary basis voltage can refer to a voltage measured at a point in the secondary utilization circuit 116 or at a secondary coil in transformer 120a-n (e.g., at metering device 11a-n). The voltage estimator 220 can determine the difference between the primary basis voltage and secondary basis voltage on a per site and per sample index basis.

The voltage estimator 220 can multiply this difference by the secondary basis voltage for the site and sample index to generate or determine a product. The voltage estimator 220 can divide this product by a secondary real demand measured or determined for the site and corresponding to the sample index to generate a quotient. The voltage estimator 220 can then perform a summation of the quotient for a plurality of samples for a particular site. The voltage estimator 220 can divide the summation by the number of samples, where the samples can correspond to a certain time interval (e.g., 12 hours, 24 hours, 48 hours, 7 days, a month, or some other time interval), to generate a second product.

The voltage estimator can further multiply the second product by a weighting function, and perform a second summation of all samples for the duration of the signal history (e.g., in days). The voltage estimator 220 can then determine, identify, or estimate the secondary impedance by dividing the second summation by a third summation of the weighting function for all historical days. The secondary impedance can correspond to a full history estimate on a per site basis.

The parameter estimator 615 can determine these parameters using the following equations or techniques:

$${ρ}_{kH} ( n ) = \frac{{\sum }_{h = 1}^{H} {w}_{k} ( n , h ) {p}_{k} ( n , h )}{{\sum }_{h = 1}^{H} {w}_{k} ( n , h ) P ( n , h )} , \\ for$$

$$1 \leq n \leq N , \\ 1 \leq k \leq K$$

$${u}_{kH} ( n ) = {\sum }_{h = 1}^{H} {w}_{k} ( n , h ) {u}_{k} ( n , h ) , \\ for$$

$$1 \leq n \leq N , \\ 1 \leq k \leq K$$

$${z}_{kH} ( n ) = \frac{{\sum }_{h = 1}^{H} {w}_{k} ( n , h ) \frac{{v}_{k} ( n , h ) ( {u}_{k} ( n , h ) - {v}_{k} ( n , h ) )}{{p}_{k} ( n , h )}}{{\sum }_{h = 1}^{H} {w}_{k} ( n , h )} , \\ for$$

$$1 \leq n \leq N , \\ 1 \leq k \leq K$$

Where:

| | |
|---|---|
| k | 1 ≦ k ≦ K AMI site index |
| h | 0 ≦ h ≦ H duration of signal history, days |
| | h = 0 is the present day |
| n | 1 ≦ n ≦ N AMI intra-day sample index |
| P(n, h) | primary real demand |
| uₖ (n, h) | primary basis voltage mean, best likely correlation with |
| | AMI site k |
| zₖ(h) | estimated secondary impedance, individual day |
| ρₖ (n, h) | estimated real demand ratio, site secondary to total |
| | primary |
| pₖ (n, h) | secondary real demand |
| vₖ (n, h) | secondary basis voltage |
| Δvₖ (n, 0) | secondary voltage drop, computed for h = 0 only |
| z_{kH}(n) | estimated secondary impedance, full history estimate |
| ρ_{kH}(n) | estimated real demand ratio, full history estimate |
| w(h) | Reference historical weights, defined on 1 ≦ h ≦ H only |
| w_{c}(n, h) | Void-compensated historical weights, defined on |
| | 0 ≦ h ≦ H only |
| β | sigmoid inflection slope for historical weights |
| u_{kH}(n) | site correlated primary basis voltage, full history estimate |
| rₖ(n) | number of void observations, AMI site k on demand |
| | interval n |

In some embodiments, the determination of the secondary impedance (or estimated secondary impedance) does not include a summation on N. By not including a summation on N, the voltage estimator can account for the impedance varying on n across history. In some cases, the voltage estimator can use a model that does not take into account varying impedances across samples or assumes minimal or no variance by summing the impedance across all intervals n. The voltage estimator may determine whether or not to sum the impedance across all intervals based on a quality of the data. For example, if the data records are coarsely divided such that interval-dependent behavior of the impedance is masked, the voltage estimator may use a summation across all intervals n.

In some embodiments, the voltage estimator 220 can determine or estimate the demand weighting parameter ρ_{kH}(n) using information from some or all of the metering sites. For example, the voltage estimator 220 can identify metering sites corresponding to a demand that is less than, equal to, or greater than a threshold. The threshold can be a fixed threshold, predetermined threshold, dynamic threshold, or adjustable threshold. For example, the threshold can be set or specified as a fraction or percentage of the mean or average secondary real demand pₖ(n, h) of the available metering sites, such as 5%, 10%, 15%, 25%, 40%, 50%, 75%, 80%, etc. of the mean secondary real demand of all the available metering sites.

The voltage estimator 220 can add or remove which metering sites are used to determine a parameter based on a comparison of a parameter of the metering site with the threshold. For example, a metering site with a secondary real demand pₖ(n, h) that is less than or equal to the threshold can indicate that the metering site corresponds to a small demand relative to the mean demand of the available metering sites. A metering site with a small demand may have minimal influence on the overall demand processes and the consequent voltage effects. Thus, the voltage estimator 220 can exclude or remove the metering sites corresponding to a secondary real demand that is less than the threshold when calculating or determining the demand weighting parameter. For example, the voltage estimator 220 can exclude or remove the metering sites having a demand less than the threshold when determining the estimated real demand ratio ρ_{kH}(n) of the site secondary to total primary. Removing the metering site can include, for example, the voltage estimator 220 removing or excluding parameters associated with the one or more metering sites having a secondary real demand less than the threshold. Parameters can include, for example, a weight, void-compensated weights, secondary real demand, estimated secondary impedance, or other parameters associated with the metering sites that are to be removed or excluded. In some cases, removing the parameter can include subtracting the parameter, filtering out the parameter, or preventing the parameter from being included in the estimate.

In some embodiments, the voltage estimator 220 can determine the secondary voltage drop estimate without quantifying the effects volt-ampere reactive power (measured in VAR) has on the secondary voltage drop. VAR is a unit in which reactive power is expressed in an alternating current (“AC”) electric power system or utility grid 100. Reactive power exists in an AC circuit when the current and voltage are not in phase. That is, the voltage estimator 220 can use the techniques disclosed herein to estimate the secondary voltage drop without using reactive power VAR measurements. This allows the voltage estimator 220 to estimate the secondary voltage drop even though meters at some residential AMI sites cannot measure and report reactive power in VAR. In some embodiments, the voltage estimator 220 receives measurements from one or more meters at one or more AMI sites, determines that the measurements do not include VAR measurements, and then selects the secondary voltage drop estimation technique that does not require quantifying reactive power.

In some embodiments, the voltage estimator 220 can quantify reactive power in VAR measurements to determine the secondary voltage drop estimate. The voltage estimator 220 can receive, via the interface, VAR measurements from one or more meters at one or more AMI sites. In some embodiments, the voltage estimator 220 can analyze or process the received measurements to determine that the measurements include VAR characteristics associated with the electricity supplied to the site. The voltage estimator 220 can further determine, responsive to identifying that VAR measurements are available for the AMI site, to use the VAR information to estimate the secondary voltage drop.

To estimate the secondary voltage drop using VAR measurements, the voltage estimator 220 can substitute a complex demand based on the VAR measurements for the real demand pₖ (n, h) in the equations above, and determine the remaining parameters and estimate the secondary voltage drop using this complex demand.

The complex demand includes the complex sum of the real and reactive components of the demand. For example, the quantity S=P+jQ is the complex demand (or power), where P is the real power (measured in Watts), Q is the reactive power, measured in VARs, and “j” is the imaginary quantity equal to the square root of minus one. The voltage estimator 220 can also include the magnitude of the complex power, or apparent power (measured in VA), which is, e.g., a square root of the sum of squared magnitudes of the real and reactive powers or \sqrt{(P²⁺ Q²)}. The reactive power can also be expressed as Q=VᵣₘₛIᵣₘₛ sin(φ), where φ is the phase angle between the current and voltage. Q can refer to the maximum value of the instantaneous power absorbed by the reactive component of the load, which can be measured by a metering device at a customer site (e.g., residential site or commercial site).

In some embodiments, the voltage estimator 220 can adjust one or more parameters based on environmental data such as ambient temperature. For example, the voltage estimator can use the ambient temperature to generate a temperature compensated demand signal. The voltage estimator 220 can provide the temperature compensated demand signal can be provided as follows: (1) if only meteorological station temperature signals are available, then adjust the primary and secondary demands assuming this temperature applies over the affected service area; or (2) if multiple temperature signals are available, spatially distributed over the service area, then create the scalar field of temperatures by using interpolation methods. In either case, the demand dependence on temperature can be a non-monotonic model around a comfort temperature zone, including polynomial models and simple linear break-point models.

The voltage estimator 220 can include a model generator 620 designed and constructed to identify, generate, or estimate a secondary voltage drop. The secondary voltage drop can refer the difference between a primary basis voltage and a secondary basis voltage. The secondary voltage drop can refer to a forecasted secondary voltage drop that is determined using measurement samples for a time interval, such as a predetermined time interval of the last 30 days, the last 7 days, the last 72 hours, the last 24 hours, etc. The secondary voltage drop can refer to the drop in voltage from a primary point in the utility grid to a secondary point in the utility grid. In some embodiments, the voltage estimator 220 can determine or estimate the secondary voltage drop based on a full history estimate of secondary impedance, the estimated real demand ratio, the primary real demand, and the full history estimate of the site correlated primary basis voltage. For example, the voltage estimator 220 can be configured with the following equation to determine the secondary voltage drop:

$$Δ {v}_{k} ( n , 0 ) = {u}_{k} ( n , 0 ) - {v}_{k} ( n , 0 ) = \frac{{z}_{kH} ( n ) {ρ}_{kH} ( n ) P ( n , 0 )}{{u}_{kH} ( n )} , \\ for$$

$$1 \leq n \leq N , \\ 1 \leq k \leq K$$

Thus, voltage estimator 220 can determine or estimate a secondary voltage drop while accounting for void samples. The secondary voltage drop can be estimated for a specific site or a metering device. The voltage estimator 220 can store the secondary voltage drop information in database 625 for further processor or provide the secondary voltage drop information to another component or module of the utility grid 100. The voltage estimator 220 can store the secondary voltage in a data structure in a storage device or memory that is structured based on a site meter.

In some embodiments, the voltage estimator 220 can generate the estimate of the secondary voltage drop based on a certain number of samples or samples corresponding to a duration. For example, the voltage estimator 220 can use metering history for 30 days. The AMI metering devices can be configured to take samples or measurements of one or more characteristics electricity for this duration. The metering device can be configured with a sample rate that facilities the systems and methods of the present disclosure. In some embodiments, the sample rate can be a value between, e.g., 1 Hz to 1 MHz. For example, the sample rate can be 900 Hz, 1800 Hz, 5 kHz, etc.

In some embodiments, the voltages used to determine one or more parameters can have a common basis, such as 120V as one power unit. In some embodiments, the system can measure or determine the demands in a common unit, such as Watts. Using Watts can facilitate determining an impedance in the unit of Ohms.

The voltage estimator 220 can apply a filter path to process measurements for primary voltages and demands. The filter path can facilitate generating a spectra of these signals that are consistent with or correspond to a nominal spectra of AMI signals. For example, the voltage estimator 220 or other component thereof can utilize a filter path as shown in FIG. 3. For example, voltage estimator 220 can include or employ one or more filters of processing element 302 configured to apply one or more filter or one or more delay to the primary voltages and demands measurements to adjust the spectra of these signals to be consistent with a spectra of the AMI signals. For example, the voltage estimator 220 can input measured signals from a metering device 118 into a first processing element 302a, and input measured signals corresponding to a primary voltage or demand (e.g., from a substation, regulator interface, or primary coil of a transformer) to a second processing element 302b. The voltage estimator 220 can then obtain an output of measured signals 306a and 306b and further process these outputs to determine the secondary voltage drop.

Upon determining the secondary voltage drop, the voltage estimator 220 can transmit this information to the voltage controller 108. The voltage controller 108 can use the determined or forecasted secondary voltage drop to update, adjust, modify, or add a desired lower bound on delivered voltage. This added lower bound on delivered voltage can be facilitate estimating a primary lower bound. For example, FIG. 5 illustrates lower bound 510.

In some embodiments, the voltage estimator 220 or voltage controller 108 can apply a smoothing function or procedure to smooth a transition between voltage settings illustrated in FIG. 5. The smoothing function or technique can include a linear or splice logistic interpolation that can facilitate moving between the settings from a prior computed interval to a new interval that is adjusted based on the estimated or forecasted secondary voltage drop.

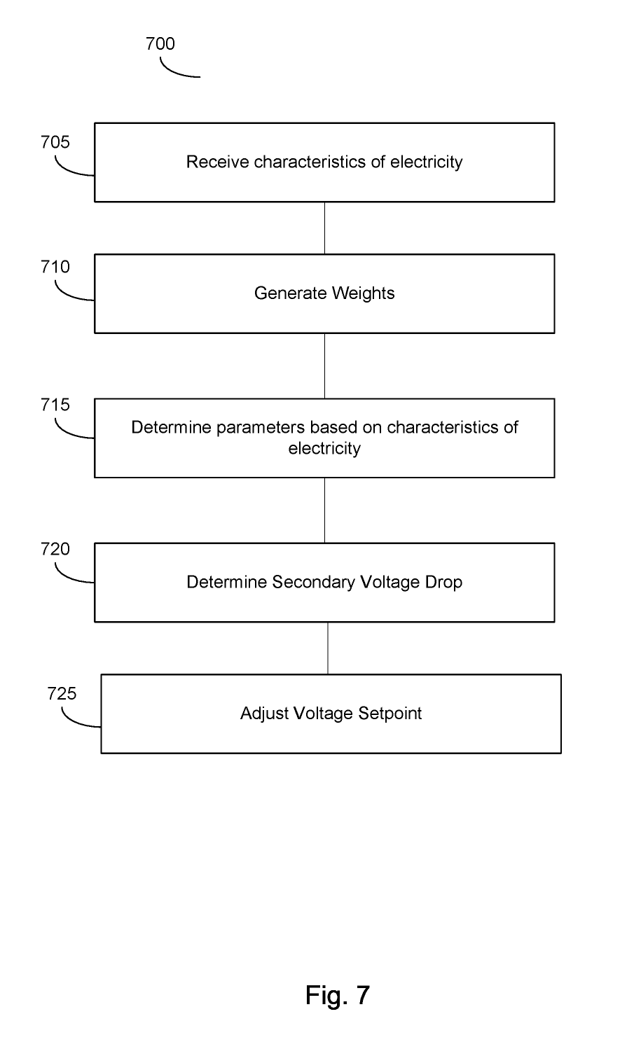

Referring now to FIG. 7, a flow diagram of an embodiment of a method 700 of estimating a secondary voltage drop in a utility grid is shown. In brief overview, and in some embodiments, a voltage estimator receives samples of characteristics of electricity at step 705. At step 710, the voltage estimator generates weights. At step 715, the voltage estimator determines one or more parameters of the utility grid, such as an impedance, a real demand ratio, a primary real demand, and a site correlated primary basis voltage. At step 720, the voltage estimator determines a secondary voltage drop. At step 725, the voltage estimator or a voltage controller adjusts a voltage setpoint for a decision boundary using the secondary voltage drop.

The method 700 can be performed by or utilize one or more system, component, module, data structure or graph illustrated in FIGS. 1-6, including, e.g., a voltage controller 118 or voltage estimator 220. In some embodiments, the voltage estimator 220, the voltage controller 118 or both can be referred to as a controller.

In brief overview, and in some embodiments, a voltage estimator receives samples of characteristics of electricity at step 705. For example, the voltage estimator can receive metered observations that are sampled at an interval (e.g., a uniform interval). The metered observation can be received from one or more meters in a utility grid, including, e.g., a meter at a substation, at a regulation site, at a regulator, at a distribution point, at a secondary circuit, at a residential site, at a commercial site, etc. In some embodiments, AMI metering devices can sense, detect or otherwise take measurements of characteristics of electricity supplied by a power source. In some embodiments, the voltage estimator can obtain information or signals relating to environmental factors such as ambient temperature, average temperature for a day or season, historical temperature, humidity, duration of daylight, etc.

In some embodiments, the voltage estimator can process the received measurement data. For example, the voltage estimator can account for missing data samples or variations using one or more filter or delay compensation techniques.

At step 710, the voltage estimator generates weights. The voltage estimator can generate the weights for the samples of the characteristics of electricity to compensate for void samples. The voltage estimator can generate the weights for the characteristics of electricity based on a validity of samples of the characteristics of electricity. The voltage estimator can generate weights that compensate for void samples at the voltage estimator (or controller). For example, a valid sample can be assigned a first weight and an invalid sample can be assigned a second weight different from the first weight. The voltage estimator can generate the first weight for the valid sample using a first weighting function. The voltage estimator can generate the second weight for the invalid sample using a second weighting function. The voltage estimator can combine the first weight generated using the first weighting function and the second weight generated using the second weighting function to generate the weights for the characteristics of electricity.

In some cases, the weights can be generated based on a sigmoid inflection slope. The voltage estimator can determine the weight for each valid sample of the samples of the characteristics of electricity using a sigmoid inflection slope for a predetermined time interval (e.g., 24 hours, 48 hours, 72 hours, 1 week, 30 days, 60 days, etc.) to generate the weights for the characteristics of electricity. The weights can be used to generate historical weights and applied to estimate parameters based on a history of samples. In some embodiments, the voltage estimator can adjust, set, or assign a weight to a sample based on whether the sample is a valid sample or an invalid sample. An invalid sample may refer to a defective or missing sample. The voltage estimator can set or assign a weight of zero or other predetermined weight to invalid samples. For valid samples, the voltage estimator can apply a weighting function based on a sigmoid inflection slope for historical weights throughout a predetermined duration of signal history (e.g., the last 30 days). The voltage estimator can combine the weights for valid and void samples to generated void-compensated historical weights.

For example, the voltage estimator can use one or more of the following weighting techniques: (1) uniformly weight the observation history for each AMI demand interval; (2) compute an intended historical weight profile with the assumption that all samples are available, and then assign zero weight to void samples, and then scale the remaining weights applied to available samples such that a sum of the applied weights is unity; or (3) compute an intended historical weight profile assuming all samples are available, assign zero weight to void samples, and then distribute the previously voided weight to the adjacent available samples.

The voltage estimator can determine, assign, or set the weights as follows to determine void-compensated historical weights.

wₖ(n,h)=w(h), for 1≦n≦N, 1≦k≦K initial weights Equation 2: Weight for valid samples.

wₖ(n,h)=0, for void observation vₖ(n,h), or pₖ(n,h) Equation 3: For invalid or void samples.

In example Equation 3, the void observations can be set to zero. The weight can be set to zero responsive to the voltage estimator determining that an observation corresponding to a secondary basis voltage signal vₖ (n, h) is missing or defective. The voltage estimator can also set the weight to zero if the observation corresponding to a secondary real demand signal pₖ(n, h) is missing or defective. The voltage estimator can combine the weights for valid samples and void samples to generate void-compensated historical weights w_{c}(n,h).

At step 715, the voltage estimator can determine one or more parameters based, at least in part, on the characteristics of electricity. The one or more parameters can be indicative of power demand of the utility grid. The voltage estimator can determine the one or more parameters using the weights applied to the samples of the characteristics of electricity. The voltage estimator can determine the parameters using the generated weights. The voltage estimator can use the void-compensated historical weights to determine parameters such as a real demand ratio, a primary basis voltage or a site correlated primary basis voltage, an impedance, or a primary real demand. The real demand ratio can refer to an estimated real demand ratio that is generated based on available historical measurements. The primary real demand can refer to a demand on a per sample basis for a certain day over a time interval (e.g., day 5 in 30 days). The estimated real demand ratio can be a ratio of a specific site's secondary real demand to a total primary real demand for each of the one or more sites. This real demand ratio for a sample with an index n on a particular day h can be determined based on combining the void-compensated historical weight with the secondary real demand. Combining the void-compensated historical weight with the secondary real demand can refer to multiplying a real demand sample on a particular day with a corresponding weight. Combining may further refer to summing the product of the real demand sample and the corresponding weight across all days throughout the historical duration (e.g., 30 days). The real demand ratio can be further determined by dividing this summation with a product of the primary real demand and corresponding weight summed across all days throughout the historical duration. Thus, the estimated real demand ratio can take into account a full history estimate as well as void samples.

The site correlated primary basis voltage can be based on available historical measurements that are correlated with an AMI metering site. The voltage estimator can generate or determine the site correlated primary basis voltage using the void-compensated historical weights. For example, the full history estimate of a particular sample of the site correlated primary basis voltage can be determined based on a product of the primary voltage mean with a corresponding void-compensated historical weight for the particular sample on a particular day. The voltage estimator can determine this product for this sample for each day in the duration, and sum or combine the products to determine the full history estimate of the site correlated primary basis voltage. Thus, the site correlated primary basis voltage can take into account a full history estimate as well as void samples.

The impedance can refer to an estimated secondary impedance, which can be based on the available historical measurements. The voltage estimator can determine the impedance based on a secondary basis voltage, primary basis voltage, secondary real demand, and void-compensated historical weights. For example, the voltage estimator can determine, for a particular AMI site and sample index, a difference between a primary basis voltage mean and a corresponding secondary basis voltage. The voltage estimator can determine a product by multiplying the difference with the same secondary basis voltage. The voltage estimator can determine a first ratio by dividing the product by the corresponding secondary real demand. Corresponding refers to a corresponding sample index and day in the historical duration. The voltage estimator can apply the void-compensated historical weight to this ratio. The voltage estimator can repeat this operation for each day in the historical duration (e.g., the last 30 days) and sum the values of a particular sample index across all days. The voltage estimator can then divide summation by a summation of the void-compensated historical weights for the specific sample index across all days to generate or determine the full history estimate of the secondary impedance.

In an illustrative example, the voltage estimator can be configured based on the following technique to determine the estimated real demand ratio, site correlated primary basis voltage, and secondary impedance based on a void-compensated weighting function.

First, the voltage estimator can acquire and buffer the previous days AMI observations.

IF (historical first-in, first-out (“fifo”) is full)

{

FOR 1 ≦ k ≦ K // each AMI site

```
{
  wₖ(n , h) = w(h) , 1 ≦ n ≦ N , 1 ≦ k ≦ K
  FOR 1 ≦ n ≦ N // AMI demand interval
  {
```

rₖ(n) = 0

FOR 1 ≦ h ≦ H // historical fifo_depth

{

IF (AMI observation at site k, interval n, day h is
void)
{

wₖ(n , h) = 0
rₖ(n) + +

}

}

| | |
|---|---|
| compute | ρ_{kH}(n) |
| compute | u_{kH}(n) |
| compute | z_{kH}(n) |

}

}

}

Upon determining the real demand ratio, primary basis voltage, and impedance using the void-compensated historical weights, the voltage estimator can be configured based on the following technique to determine the secondary voltage drop:

FOR 1 ≦ n ≦ N // AMI demand interval

```
  {
  Acquire P(n , 0) // applicable primary demand, present cycle
  FOR 1 ≦ k ≦ K // AMI sites
```

{
Acquire uₖ(n , 0) // applicable primary voltage estimate, present
cycle, signal db
Compute Δvₖ(n , 0)

}
}

In some embodiments, the voltage estimator can remove or exclude one or more sites and their corresponding parameters from being used to determine the secondary voltage drop or other parameters used to adjust the voltage setpoint. For example, if a demand for a site is below a threshold, then the voltage estimator can determine that it is inconsequential or have minimal impact on adjusting the voltage setpoint, and, therefore, remove the characteristics of electricity or parameters thereof from being used to compute the secondary voltage drop, for example. By excluding or removing one or more sites based on the threshold, the voltage estimator can improve the efficiency with which the voltage estimator determines the voltage setpoint adjustment. For example, the voltage estimator can reduce resource consumption (e.g., processor utilization, bandwidth, I/O requests, or memory usage) by determining the secondary voltage drop and adjusting the setpoint by excluding metering sites and data from those metering sites.

To determine which metering sites to exclude, the voltage estimator can compare a real demand of a metering site with a threshold. Responsive to the comparison of the site's real demand with the threshold, the voltage estimator can remove the site from being used for further processing. For example, if the site's demand is less than or equal to the threshold, the voltage estimator can remove the site from being used for further processing.

The voltage estimator can determine the threshold based on a mean or average demand for the one or more metering sites or all available metering sites in the utility grid or all metering sites for which the voltage estimator has metered observations during a time interval. For example, the threshold can be a fraction or percentage of the mean demand of the available metering sites, such as 5%, 10%, 20%, 25%, 30%, 45%, 50%, 60%, 70%, etc.

At step 720, the voltage estimator can determine a secondary voltage drop based, at least in part, on the one or more parameters. The voltage estimator can determine the secondary voltage drop based on the determined real demand ratio, the primary basis voltage, and the impedance. The secondary voltage drop can correspond to a distribution transformer located between a primary distribution level of the utility grid and a secondary distribution level of the utility grid corresponding to the one or more sites. The secondary voltage drop, or forecasted or estimated secondary voltage drop, can be determined as a product of an impedance, a real demand ratio, and a primary real demand divided by a site correlated primary basis voltage. The secondary voltage drop can be determined on a per AMI metering site basis. The secondary voltage drop can use void-compensated historical weights to determine one or more parameters, characteristics of values.

At step 725, the voltage estimator, voltage controller, or controller adjusts a voltage setpoint for a decision boundary using the secondary voltage drop. For example, the controller can adjust, based on the determined secondary voltage drop, a decision boundary for a primary voltage setpoint. The decision boundary for the primary voltage setpoint can be used to establish a voltage level provided to the distribution transformer by a regulating transformer located at the primary distribution level.

The voltage controller can obtain, from the voltage estimator, the secondary voltage and adjust a primary distribution voltage setpoint in an elastic decision boundary used by a voltage control system to adjust tap settings (e.g., as illustrated in FIG. 5). This voltage setpoint can be used as the basis for computing decision threshold and be adjusted on a continuous, periodic, or some other basis using the secondary voltage drop estimate. In some embodiments, the voltage setpoint can be adjusted on an hourly basis, per sample basis, daily basis, weekly basis, or responsive to a condition or vent (e.g., falling below a minimum threshold or above a maximum threshold).

In some implementations, a voltage estimator (e.g., via a weighting module, parameter estimator, or model generator) can determine the primary voltage setpoint lower bound. The system can use the primary voltage setpoint lower bound to control the voltage in a distribution grid. The voltage estimator can use the determined secondary voltage drop time series for AMI metering sites. In some cases, the voltage estimator may have access to or use information from all available secondary delivery points configured with AMI meters, while in other cases the voltage estimator may use information from a subset of AMI meters. In some cases, the system can select a subset of AMI meters based on one or more characteristics, such as those meters with a lowest voltage characteristic.

The voltage estimator can determine an available reduction in the primary voltage lower bound. Adjusting the primary voltage lower bound can affect how the voltage controller adjusts a tap setting of a voltage regulator transformer via a regulator interface. The available reduction in the primary voltage lower bound (e.g., 510 shown in FIG. 5) can be based on a site correlated primary basis voltage and a secondary voltage drop determined by the voltage estimator. For example, the reduction in the primary voltage lower bound can be the difference between the site correlated primary basis voltage, the minimum allowable delivery site voltage, and an average secondary voltage drop.

In some cases, the voltage estimator may determine a secondary voltage drop based on a subset of sites. For example, the voltage estimator can sort the metering sites based on their respective secondary voltage drops, and select a subset of the sites. For example, the voltage estimator can form a subset of metering sites from an upper quartile of secondary voltage drops, top quartile, top third, top half, middle quartile, etc. For example, the voltage estimator can sort or rank the secondary voltage drops, and select the highest quartile of secondary voltage drop values. The voltage estimator can determine a mean or average based on the highest quartile of secondary voltage drop values. The voltage estimator can then determine an amount by which the primary voltage lower bound can be reduced based on a difference between a site correlated primary basis voltage, an allowable delivery site voltage (e.g., a minimum allowable delivery site voltage), and the average secondary voltage drop for the highest quartile. In some cases, the voltage estimator can determine an amount by which the primary voltage lower bound can be reduced based on a difference between a site correlated primary basis voltage, a minimum allowable delivery site voltage, the average secondary voltage drop for the highest quartile, and a secondary voltage drop error.

To determine an amount by which to reduce a primary voltage lower bound in an elastic decision boundary, the voltage estimator can use Δvₖ (n, 0) as determined based on a secondary impedance, real demand ratio, and primary voltage historical locations as follows:

$$Δ {v}_{k} ( n , 0 ) = \frac{{z}_{kH} ( n ) {ρ}_{kH} ( n ) P ( n , 0 )}{{u}_{kH} ( n )} .$$

The voltage estimator can be configured with the following parameters to determine the reduction in the primary voltage lower bound. The voltage estimator can obtain, retrieve, receive or determine one or more of the following values. The voltage estimator can access a data structure (e.g., a meter observation data structure or signal database) storing these values, parameters, observations, or definitions, including, for example:

| | |
|---|---|
| K | number of AMI metering sites |
| Kₘᵢₙ | minimum number of AMI metering sites permitted for |
| | estimates |
| N | number of AMI demand intervals in a demand cycle |
| | (one day) |
| M | number of Adapti Volt primary estimation intervals |
| | in a demand cycle |
| M_{Adj} | number of primary voltage setpoint adjustment |
| | intervals in a demand cycle |
| Δv_{Error} | secondary voltage estimation error allowance, |
| | configured as basis volts |
| v_{SecMinSite} | minimum allowable delivery site voltage, basis volts |
| h_{Adj} | primary lower bound adjustment filter |
| Floor | round down to nearest integer |
| Mean | unweighted average |
| Var | variance using Mean as location estimate |
| k | 1 ≦ k ≦ K AMI site index |
| n | 1 ≦ n ≦ N AMI intra-day sample index |
| | for N demand intervals |
| m | 1 ≦ m ≦ M Adapti Volt primary estimate index |
| | for M estimates per day |
| Δt_{AMI} | assumed uniform AMI demand period, such that |
| | NΔt_{AMI} is one day |
| Δt_{PRI} | uniform primary sample period, such that MΔt_{PRI} is |
| | one day |
| P (m, 0) | present primary real demand |
| Δvₖ(:, 0) | secondary voltage drop, computed for h = 0 only |
| z_{kH}(n) | estimated secondary pseudo-impedance, full history |
| | estimate |
| ρ_{kH}(n) | estimated real demand ratio, full history estimate |
| u_{kH}(n) | site correlated primary basis voltage, full history |
| | estimate |
| σ_{H}²(:) | variance estimate, secondary voltage drop |
| σ_{Huq}²(:) | variance estimate, secondary voltage drop, |
| | trimmed upper quartile subset |
| K_{q} | number of AMI sites in trimmed upper quartile subset |
| Δv_{Huq}(:) | mean secondary voltage drop, trimmed upper quartile |
| | subset |
| Δv_{Sec}(m) | estimated aggregate secondary voltage drop |
| Δu_{VipLowBound}(m) | estimated available reduction in primary voltage lower |
| | bound |

The voltage estimator can be configured with or implement the following technique to determine or estimate the available reduction in primary voltage lower bound:

| | |
|---|---|
| FOR 1 ≦ m ≦ M | // primary estimation interval |

{

| | |
|---|---|
| Acquire P(m, 0) | // applicable primary demand, present cycle |

n = Floor(mΔt_{PRI} / Δt_{AMI})
Fetch Z_{kH}(n), ρ_{kH}(n), u_{kH}(n)

| | |
|---|---|
| FOR 1 ≦ k ≦ K | // AMI sites |

{

| | |
|---|---|
| Acquire uₖ(m, 0) | // from signal database or meter observation data |
| | structure |

${Δv}_{k} ( m , 0 ) = \frac{{z}_{kH} ( n ) {ρ}_{kH} ( n ) P ( m , 0 )}{{u}_{kH} ( n )}$
}
// Identify upper quartile subset
Determine σ_{H}²(m) = Var(Δvₖ(m, 0))
Sort Δvₖ(m, 0) by magnitude, retain site index k
Select upper quartile of sorted Δvₖ(m, 0) (referred to as Δv_{kuq}(m))
Determine σ_{Huq}²(m) = Var(Δv_{kuq}(m)) on upper quartile
// Trim upper quartile subset
WHILE σ_{Huq}²(m) > (K_{q} / K)σ_{H}²(m) AND K_{q} ≧ Kₘᵢₙ
{
Remove smallest Δv_{kuq}(m) from upper quartile subset
K_{q} —
}
Determine Δv_{Sec}(m) = Mean_{kuq} (Δv_{kuq}(m))
Determine Δu_{VipLowBound}(m) = uₖ(m, 0) − v_{SecMinSite} − Δv_{Sec}(m) − Δv_{Error}
}

Adjust or reduce primary voltage lower bound:

FOR 1 ≦ m_{Adj} ≦ M_{Adj} // primary estimation interval
{
Δu_{VipLowBound}(m_{Adj}) = Δu_{VipLowBound}(m) * h_{Adj} for prior Floor(M/M_{Adj})
estimates
}

In some embodiments, the voltage estimator or voltage controller generates a control signal based on the adjusted voltage setpoint. The voltage estimator or voltage controller an generate the control signal based on a primary voltage lower bound reduced by Δu_{VipLowBound}(m_{Adj}). Using the adjusted or reduced voltage primary voltage lower bound, the voltage controller can generate a control signal to adjust a tap setting of a voltage regulator transformer. The control signal can increase the tap setting or lower the tap setting based on the result of the decision boundary. For example, if the voltage controller determines that a primary voltage is too low based on a decision boundary, then the voltage controller can generate a signal to increase an output voltage of the voltage regulator transformer.

For example, the voltage estimator or controller can adjust the decision boundary which can include a primary lower bound. The controller can determine the primary voltage setpoint using the adjusted primary lower bound. The controller can provide a signal to adjust a tap setting of the regulating transformer responsive to implementation of the control processes using the determined voltage setpoint.

In some embodiments, systems and methods of the present disclosure can determine a secondary voltage drop in an electric utility grid with minimal signal complement and control the distribution circuit primary voltage. The secondary voltage drop can be based on a difference between a primary basis voltage that is correlated with an AMI site and a secondary basis voltage drop. The system determines the secondary voltage drop using void-compensated weights to determine a historical estimate of a secondary impedance, a historical estimate of a real demand ratio, a primary real demand, and a primary basis voltage correlated with an AMI site. The system determines a first product of the historical secondary estimated impedance, the estimated real demand ratio (e.g., ratio of an AMI site's secondary voltage to a total primary voltage), and the primary real demand. The system divides the first product by the site correlated primary basis voltage to determine the secondary voltage drop.

While this specification contains many specific implementation details, these should not be construed as limitations on the scope of any inventions or of what can be claimed, but rather as descriptions of features specific to particular embodiments of particular aspects. Certain features described in this specification in the context of separate embodiments can also be implemented in combination in a single embodiment. Conversely, various features described in the context of a single embodiment can also be implemented in multiple embodiments separately or in any suitable subcombination. Moreover, although features can be described above as acting in certain combinations and even initially claimed as such, one or more features from a claimed combination can in some cases be excised from the combination, and the claimed combination can be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing can be advantageous. Moreover, the separation of various system components in the embodiments described above should not be understood as requiring such separation in all embodiments, and it should be understood that the described program components and systems can generally be integrated in a single software product or packaged into multiple software products.

References to “or” can be construed as inclusive so that any terms described using “or” can indicate any of a single, more than one, and all of the described terms.

Thus, particular embodiments of the subject matter have been described. In some cases, the actions recited in the claims can be performed in a different order and still achieve desirable results. In addition, the processes depicted in the accompanying figures do not necessarily require the particular order shown, or sequential order, to achieve desirable results.

What is claimed is:

1. A method of managing power delivery in a utility grid, comprising:
receiving, by a controller from one or more metering devices, samples of characteristics of electricity delivered from a power source to one or more sites;
generating, by the controller, weights for the samples of characteristics of electricity to compensate for void samples;
determining, by the controller, one or more parameters indicative of power demand of the utility grid using the weights applied to the samples of characteristics of electricity;
determining, by the controller, a secondary voltage drop based on the one or more parameters determined using the weights applied to the samples of characteristics of electricity, the secondary voltage drop corresponding to a distribution transformer located between a primary distribution level of the utility grid and a secondary distribution level of the utility grid corresponding to the one or more sites; and
adjusting, by the controller, based on the determined secondary voltage drop, a primary voltage setpoint used to establish a voltage level provided to the distribution transformer by a regulating transformer located at the primary distribution level.

2. The method of claim 1, comprising:
receiving, by the controller during a first time interval, a first plurality of samples of the characteristics of electricity from the one or more metering devices corresponding to the one or more consumer sites, the first plurality of samples correlated with the one or more metering devices; and
receiving, by the controller during a second time interval, a second plurality of samples of the characteristics of electricity from the one or more metering devices corresponding to the one or more consumer sites, the second plurality of samples correlated with the one or more metering devices, wherein the characteristics of electricity indicate at least one of voltage information, primary voltage information, secondary voltage information, primary real demand, or secondary real demand.

3. The method of claim 2, comprising:
determining, by the controller, the secondary voltage drop based on the one or more parameters determining using the characteristics of electricity delivered during the first time interval and the characteristics of electricity delivered during the second time interval.

4. The method of claim 1, comprising:
generating, by the controller for each valid sample of the samples of the characteristics of electricity, a weight using a first weighting function;
generating, by the controller for each invalid sample of the samples of the characteristics of electricity, a weight using a second weighting function; and
combining, by the controller, the weight generated using the first weighting function and the weight generated using the second weighting function to generate the weights for the characteristics of electricity.

5. The method of claim 1, comprising:
determining, by the controller for each valid sample of the samples of the characteristics of electricity, a weight using a sigmoid inflection slope for a predetermined time interval to generate the weights for the samples of the characteristics of electricity.

6. The method of claim 1, comprising:
determining, by the controller, the one or more parameters comprising a real demand ratio for each of the one or more sites based on a ratio of a secondary real demand to a primary real demand for each of the one or more sites.

7. The method of claim 1, comprising:
determining, by the controller, a real demand for at least one metering site of the one or more metering sites; and
excluding, by the controller responsive to a comparison of the real demand for the at least one metering site with a threshold, the at least one metering site from the determination of the secondary voltage drop.

8. The method of claim 1, comprising:
determining, by the controller, a threshold based on a mean demand for the one or more metering sites;
determining, by the controller, that a real demand for at least one metering site of the one or more metering sites is less than or equal to the threshold; and
excluding, by the controller responsive to the real demand for the at least one metering site less than or equal to the threshold the at least one metering site from the determination of the secondary voltage drop.

9. The method of claim 1, wherein the secondary voltage drop comprises a sum of voltage drops in conductors connecting the one or more consumer sites to a secondary terminal of the distribution transformer and a voltage drop in the distribution transformer due to loading.

10. The method of claim 1, comprising:
adjusting, by the controller, the decision boundary comprising a primary lower bound based on the secondary voltage drop;
determining, by the controller, the primary voltage setpoint using the adjusted primary lower bound; and
providing, by the controller, a signal to adjust a tap setting of the regulating transformer responsive to implementation of the control processes using the determined voltage setpoint.

11. A system to manage power delivery in a utility grid, comprising:
a controller comprising one or more processors configured to:
receive, from one or more metering devices, samples of characteristics of electricity delivered from a power source to one or more consumer sites;
generate weights for the samples of characteristics of electricity to compensate for void samples;
determine one or more parameters indicative of power demand of the utility grid using the weights applied to the samples of characteristics of electricity;
determine a secondary voltage drop based on the one or more parameters determined using the weights applied to the samples of characteristics of electricity, the secondary voltage drop corresponding to a distribution transformer located between a primary distribution level of the utility grid and a secondary distribution level of the utility grid corresponding to the one or more sites; and
adjust, based on the determined secondary voltage drop, a primary voltage setpoint used to establish a voltage level provided to the distribution transformer by a regulating transformer located at the primary distribution level.

12. The system of claim 11, wherein the controller is further configured to:
receive, during a first time interval, a first plurality of samples of the characteristics of electricity from the one or more metering devices corresponding to the one or more consumer sites, the first plurality of samples correlated with the one or more metering devices; and
receive, during a second time interval, a second plurality of samples of the characteristics of electricity from the one or more metering devices corresponding to the one or more consumer sites, the second plurality of samples correlated with the one or more metering devices, wherein the characteristics of electricity indicate at least one of voltage information, primary voltage information, secondary voltage information, primary real demand, or secondary real demand.

13. The system of claim 12, wherein the controller is further configured to:
determine the secondary voltage drop based on the one or more parameters determining using the characteristics of electricity delivered during the first time interval and the characteristics of electricity delivered during the second time interval.

14. The system of claim 11, wherein the controller is further configured to:
generate, for each valid sample of the samples of the characteristics of electricity, a weight using a first weighting function;
generate, for each invalid sample of the samples of the characteristics of electricity, a weight using a second weighting function; and
combine the weight generated using the first weighting function and the weight generated using the second weighting function to generate the weights for the characteristics of electricity.

15. The system of claim 11, wherein the controller is further configured to:
determine, for each valid sample of the samples of the characteristics of electricity, a weight using a sigmoid inflection slope for a predetermined time interval to generate the weights for the characteristics of electricity.

16. The system of claim 11, wherein the controller is further configured to:
determine a real demand ratio for each of the one or more sites based on a ratio of a secondary real demand to a primary real demand for each of the one or more sites.

17. The system of claim 11, wherein the controller is further configured to:
determine a real demand for at least one metering site of the one or more metering sites; and
exclude, responsive to a comparison of the real demand for the at least one metering site with a threshold, the at least one metering site from the determination of the secondary voltage drop.

18. The system of claim 12, wherein the controller is further configured to:
determine a threshold based on a mean demand for the one or more metering sites;
determine that a real demand for at least one metering site of the one or more metering sites is less than or equal to the threshold; and
exclude, responsive to the real demand for the at least one metering site less than or equal to the threshold the at least one metering site from the determination of the secondary voltage drop.

19. The system of claim 11, wherein the secondary voltage drop comprises a sum of voltage drops in conductors connecting the one or more consumer sites to a secondary terminal of the distribution transformer and a voltage drop in the distribution transformer due to loading.

20. The system of claim 11, wherein the controller is further configured to:
adjust the decision boundary comprising a primary lower bound based on the secondary voltage drop;
determine the primary voltage setpoint using the adjusted primary lower bound; and
provide a signal to adjust a tap setting of the regulating transformer responsive to implementation of the control processes using the determined voltage setpoint.
